(19) United States
(12) Patent Application Publication
(10) Pub. No.: US 2024/0337945 A1
(43) Pub. Date: Oct. 10, 2024

(54) THICK FILM-FORMING COMPOSITION AND METHOD FOR MANUFACTURING CURED FILM USING THE SAME

(71) Applicant: MERCK PATENT GMBH, DARMSTADT (DE)

(72) Inventors: YOSHIO NOJIMA, SHIZUOKA (JP); TAKASHI SEKITO, SHIZUOKA (JP); HIROSHI HITOKAWA, SHIZUOKA (JP); TAKANORI KUDO, BEDMINSTER, NH (US)

(21) Appl. No.: 18/743,005

(22) Filed: Jun. 13, 2024

Related U.S. Application Data
(63) Continuation of application No. PCT/EP2022/085112, filed on Dec. 9, 2022.
(60) Provisional application No. 63/265,315, filed on Dec. 13, 2021.

(51) Int. Cl. G03F 7/11; C09D 165/00

(52) U.S. Cl. CPC G03F 7/11; C09D 165/00

(57) ABSTRACT

A thick film-forming composition comprising a hydrocarbon-containing compound (A) as defined herein and a solvent (B). The solvent (B) may be an organic solvent (B1) and may have a dielectric constant of 20.0 to 90.0. The film thickness of the film formed from the thick film-forming composition is 0.5 to 10 μm.

### CROSS-REFERENCE TO RELATED APPLICATION

This application is a Continuation under 35 USC § 111(a) of International Patent Application No. PCT/EP2022/085112 filed Dec. 9, 2022, which claims benefit of Provisional Application No. 63/265,315 filed on Dec. 13, 2021. The entire contents of these applications are incorporated herein by reference in their entirety.

### BACKGROUND OF THE INVENTION

### Technical Field

The present invention relates to a thick film-forming composition and a method for manufacturing a cured film using the same.

### Background Art

In a process of manufacturing a semiconductor, fine processing by lithographic technique using a photoresist (hereinafter, also referred to as the resist) has generally been employed. The fine processing process comprises forming a thin photoresist layer on a semiconductor substrate such as a silicon wafer, covering the layer with a mask pattern corresponding to a desired device pattern, exposing the layer with actinic ray such as ultraviolet ray through the mask, developing the exposed layer to obtain a photoresist pattern, and etching the substrate using the resulting photoresist pattern as a protective film, thereby forming fine unevenness corresponding to the above-described pattern.

Use of ultraviolet ray of single wavelength (for example, KrF light source of 248 nm) causes a problem that the dimensional accuracy of the resist pattern is reduced due to the influence of standing wave. Then, in order to solve this problem, a method for preparing a bottom anti-reflective coating film has been widely studied. The feature required for such a bottom anti-reflective coating film is that the anti-reflective effect is high, and the like.

In order to achieve further finer processing, methods using an ArF light source (193 nm) or EUV (13 nm) have been widely studied. In this case, if the film thickness of the resist is too thick, the resist pattern is likely to collapse or a development residue is likely to be generated. Therefore, there is a problem that a sufficient function of the protective film cannot be obtained only by the resist.

Therefore, a method called multi-layer has been widely used, in which a new protective film is formed as a underlayer of a photoresist, a photoresist pattern is transferred to the underlayer film, and the substrate is etched using the underlayer film as a protective film.

Various types of multi-layer protective film exist, and an amorphous carbon film is sometimes used as the protective film.

As a method for increasing the function of the protective film of carbon film by applying a solution and baking, a method for applying a solution to form a carbon film that can withstand baking at a temperature exceeding the general baking temperature of 450° C., and baking, for example, at 600° C. is mentioned. In addition, the function of the protective film can be improved by increasing the carbon concentration in the solid of the carbon film-forming solution, but it is general to trade off with other performances such as solubility.

In such a technical situation, Patent Document 1 studies a method for manufacturing a cured film by applying a composition comprising an organic compound having an aromatic ring unit, and subjecting it to first heating in an atmosphere having an oxygen concentration of less than 10% and then second heating in an atmosphere having an oxygen concentration of 10% or more at a high temperature of, for example, 350° C.

Patent Document 2 studies a method for increasing the carbon concentration to improve the etching resistance by applying a composition comprising fullerene and subjecting it to heating and curing at a high temperature of, for example, 350° C.

In the above studies, a cured film of a thin film of about 200 to 300 nm has been studied, but it has been required that a cured film having the same characteristics can be produced even in a film thicker than this range. It is difficult for a thick film to achieve a film quality having a better function as a protective film than a thin film.

### PRIOR ART DOCUMENTS

### Patent Documents

[Patent Document 1] JP 2014-219559 A
[Patent Document 2] WO 2018/115043

### Non-Patent Documents

[Non-Patent Document 1] “Identification of high performance solvents for the sustainable processing of graphene” (H. J. Salavagione et al., Green Chemistry 2017 Issue 19 p2550)

### SUMMARY OF THE INVENTION

### Problems to be Solved by the Invention

The present inventors considered that it would be useful in the manufacturing process if a thick cured film showing good properties could be formed even when heated at a low temperature. The present inventors considered that there are one or more problems that still need improvements. These include, for example, the following: To obtain a thick cured film; to obtain a cured film by low-temperature heating; to avoid damage given to other layers in the process; to obtain a cured film with a high film density; to obtain a cured film with a high film hardness; to obtain a film with good indentation hardness; to obtain a cured film with good indentation elasticity; to obtain a cured film with high etching resistance; to obtain a cured film with high resistance to ion implantation treatment; to obtain a cured film with a small amount of shrinkage even after undergoing ion implantation treatment; to obtain a cured film with good filling properties; solubility in the solvent is high; flatness of the cured film is high; to obtain a composition with high viscosity; to promote the curing reaction; and to eliminate intermixing with the upper layer film to reduce the diffusion of low molecular weight components into the upper layer.

### Means for Solving the Problem

Thick film-forming composition according to the present invention comprises a hydrocarbon-containing compound (A) and a solvent (B):
wherein,
the hydrocarbon-containing compound (A) comprises the unit (A1) represented by the formula (A1):

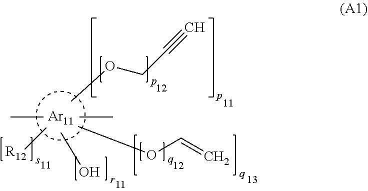

where,
Ar₁₁ is a C₆₋₆₀ hydrocarbon group substituted with R₁₁ or unsubstituted,
R₁₁ is C₁₋₂₀ alkyl, amino or C₁₋₂₀ alkylamino,
R₁₂ is I, Br or CN, and
p₁₁ is a number of 0 to 5, p₁₂ is a number of 0 to 1, q₁₁ is a number of 0 to 5, q₁₂ is a number of 0 to 1, r₁₁ is a number of 0 to 5, s₁₁ is a number of 0 to 5, provided that p₁₁, q₁₁ and r₁₁ do not become 0 simultaneously in one unit;
the solvent (B) comprises an organic solvent (B1) and an organic solvent (B2) having a dielectric constant of 20.0 to 90.0; and
the film thickness of the film formed from the thick film-forming composition is 0.5 to 10 μm.

The method for manufacturing a cured film according to the present invention comprises the following processes:
(1) applying the above-mentioned composition above a substrate to form a hydrocarbon-containing film; and
(2) heating the hydrocarbon-containing film:
   wherein,
the film thickness of the cured film is 0.5 to 10 μm.

The method for manufacturing a resist film according to the present invention comprises the following processes:
manufacturing a cured film by the above-mentioned method;
(3) applying a resist composition above the cured film; and
(4) heating the resist composition to form a resist film.

The method for manufacturing a resist pattern according to the present invention comprises the following processes:
manufacturing a resist film by the above-mentioned method;
(5) performing the exposure to the resist film; and
(6) developing the resist film.

The method for manufacturing a processed substrate according to the present invention comprises the following processes:
manufacturing a resist pattern by the above-mentioned method; and
(7) processing the underlayer of the resist pattern using the resist pattern as a mask.

The method for manufacturing a device according to the present invention comprises the above-mentioned method.

### Effects of the Invention

Using the method for manufacturing a cured film of the present invention, it is possible to desire one or more of the following effects. It is possible to obtain a thick cured film; it is possible to obtain a cured film by low-temperature heating; it is possible to avoid damage given to other layers in the process; it is possible to obtain a cured film with a high film density; it is possible to obtain a cured film with a high film hardness; it is possible to obtain a film with good indentation hardness; it is possible to obtain a cured film with good indentation elasticity; it is possible to obtain a cured film with high etching resistance; it is possible to obtain a cured film with high resistance to ion implantation treatment; it is possible to obtain a cured film with a small amount of shrinkage even after undergoing ion implantation treatment; it is possible to obtain a cured film with good filling properties; solubility in the solvent is high; flatness of the cured film is high; it is possible to obtain a composition with high viscosity; it is possible to promote the curing reaction by containing an organic solvent having a high dielectric constant; and it is possible to eliminate intermixing with the upper layer film or to reduce the diffusion of low molecular weight components into the upper layer.

### DETAILED DESCRIPTION OF THE INVENTION

### Mode for Carrying Out the Invention

Embodiments of the present invention are described below in detail.

### [Definitions]

Unless otherwise specified in the present specification, the definition and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, the compound itself that generates a base). An embodiment in which the compound is dissolved or dispersed in a solvent and added to the composition is also possible.

As one embodiment of the present invention, it is preferable that such a solvent is contained in the composition according to the present invention as the solvent (B) or another component.

### [Thick Film-Forming Composition}

### Hydrogen-Containing Compound (A)

The composition according to the present invention comprises a hydrocarbon-containing compound (A) (hereinafter, sometimes referred to as the component (A); the same applies to other components). The hydrocarbon-containing compound (A) comprises a unit (A1) represented by the formula (A1).

The component (A) is acceptable as long as it contains the unit (A1), and it is accepted to contain other constitutional units. When the component (A) contains another constitutional unit and the component (A) is a polymer, it is a preferable embodiment that the unit (A1) and the other constitutional unit are copolymerized. As a preferred embodiment of the present invention, the component (A) substantially consists of only the unit (A1). However, terminal modification is acceptable.

The formula (A1) is as follows:

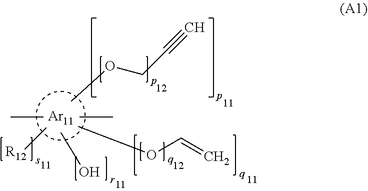

where,
Ar₁₁ is a C-60 hydrocarbon group substituted with R₁₁ or unsubstituted. Ar₁₁ preferably does not contain a naphthyl ring (more preferably does not contain any fused aromatic ring). Preferable Ar₁₁ include 9,9-diphenyl-fluorene, 9-phenylfluorene, phenyl, C₆₋₆₀ linear polyphenylene and C₆₋₆₀ branched polyphenylene, each of which can be each independently substituted with R₁₁ or unsubstituted. It is also a preferred embodiment of the present invention that Ar₁₁ is unsubstituted.
R₁₁ is C₁₋₂₀ alkyl, amino or C₁₋₂₀ alkylamino. The alkyl can be linear, branched or cyclic. R₁₁ is preferably C₁₋₁₀ alkyl or C₁₋₁₀ alkylamino (more preferably C₁₋₃ linear alkyl, C₁₋₃ branched alkyl, cyclopentyl, cyclohexyl or dimethylamino).
R₁₂ is I, Br or CN (preferably I or Br; more preferably I).
p₁₁ is a number of 0 to 5. As an embodiment of the present invention, the component (A) can have only one each of the unit (A1) of two types as a configuration. There can be an embodiment in which Ar₁₁ is both phenyl, p₁₁=1 for one Ar₁₁, and p₁₁=2 for the other Ar₁₁. In this case, p₁₁=1.5 as a whole. The same applies to the numbers in the present specification, unless otherwise noted. p₁₁ is preferably 0, 1, 2 or 3 (more preferably 0, 1 or 2; further preferably 1). p₁₁=0 is also a preferred embodiment of the present invention.
p₁₂ is a number of 0 to 1 (preferably 0 or 1; more preferably 1).
q₁₁ is a number of 0 to 5 (preferably 0, 1, 2 or 3; more preferably 0, 1 or 2; further preferably 1). q₁₁=0 is also a preferred embodiment of the present invention.
q₁₂ is a number of 0 to 1 (preferably 0 or 1; more preferably 1). r₁₁ is a number of 0 to 5 (preferably 0, 1, 2 or 3; more preferably 0, 1 or 2; further preferably 1). r₁₁=0 is also a preferred embodiment of the present invention.
s₁₁ is a number of 0 to 5 (preferably 0, 1, 2 or 3; more preferably 0, 1 or 2; further preferably 1). s₁₁=0 is also a preferred embodiment of the present invention.

Provided that, p₁₁, q₁₁ and r₁₁ do not become 0 simultaneously in one unit;

When the component (A) has a plurality of units (A1), R₁₁ can intervene between each Ar₁₁ and bind them as a linker. The number of R₁₁ substituting one Ar₁₁ can be one or more; preferably one.

In one unit (A1), the group enclosed in parentheses (for example, the group enclosed in parentheses to which p₁₁ is attached) can be bonded to R₁₁. In this case, R₁₁ intervenes and bind such a group and Ar₁₁ as a linker.

For example, the compound on the left below can be understood as a component (A) composed of two units (A1). Ar₁₁ in one unit (A1) is 9-phenylfluorene, and Ar₁₁ in the other unit (A1) is 9,9-diphenylfluorene. In either unit (A1), p₁₁=1 and q₁₁=r₁₁=s₁₁=0. As shown on the right side below, in each of the two units (A1), one bond indicated by the arrow is not used for bonding to the other unit.

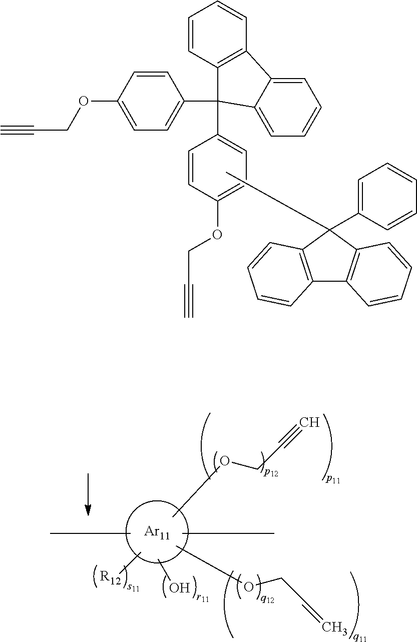

The formula (A1) is preferably the formulae (A1-1), (A1-2), (A1-3) and/or (A1-4).

The formula (A1-1) is as follows.

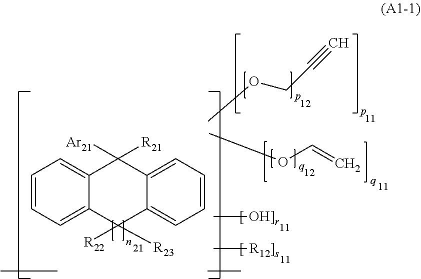

where,

Ar₂₁ is a C₆₋₅₀ aromatic hydrocarbon group. Although not to be bound by theory, Ar₂₁ is preferably phenyl because it can ensure the solubility of the component (A) in the solvent and can be expected to have advantageous effects such as the formation of a thick film. Ar₂₁ preferably does not contain any fused aromatic ring.

R₂₁, R₂₂ and R₂₃ are each independently a C₆₋₅₀ aromatic hydrocarbon group, hydrogen, or a single bond bonded to another structural unit. Preferably R₂₁, R₂₂ and R₂₃ do not contain naphthyl (more preferably fused aromatic rings). R₂₁, R₂₂ and R₂₃ are preferably phenyl, hydrogen, or a single bond bonded to another structural unit (more preferably phenyl or a single bonds bonded to another structural units; further preferably phenyl).

n₂₁ is 0 or 1 (preferably 0).

The definitions and preferred examples of R₁₂, p₁₁, p₁₂, q₁₁, q₁₂, r₁₁ and s₁₁ are each independently the same as above.

Examples of the component (A) having the structure of the formula (A1-1) include the following.

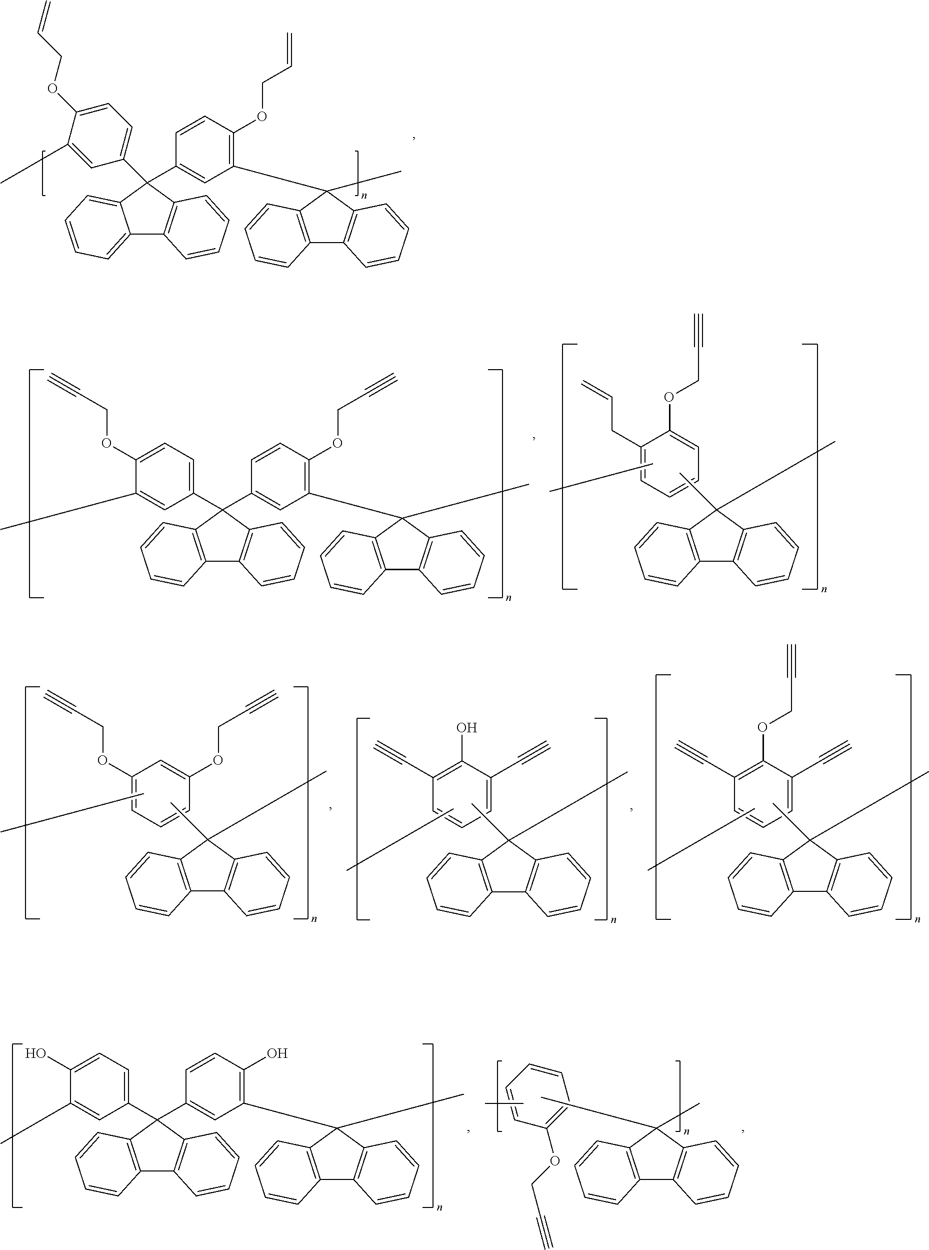

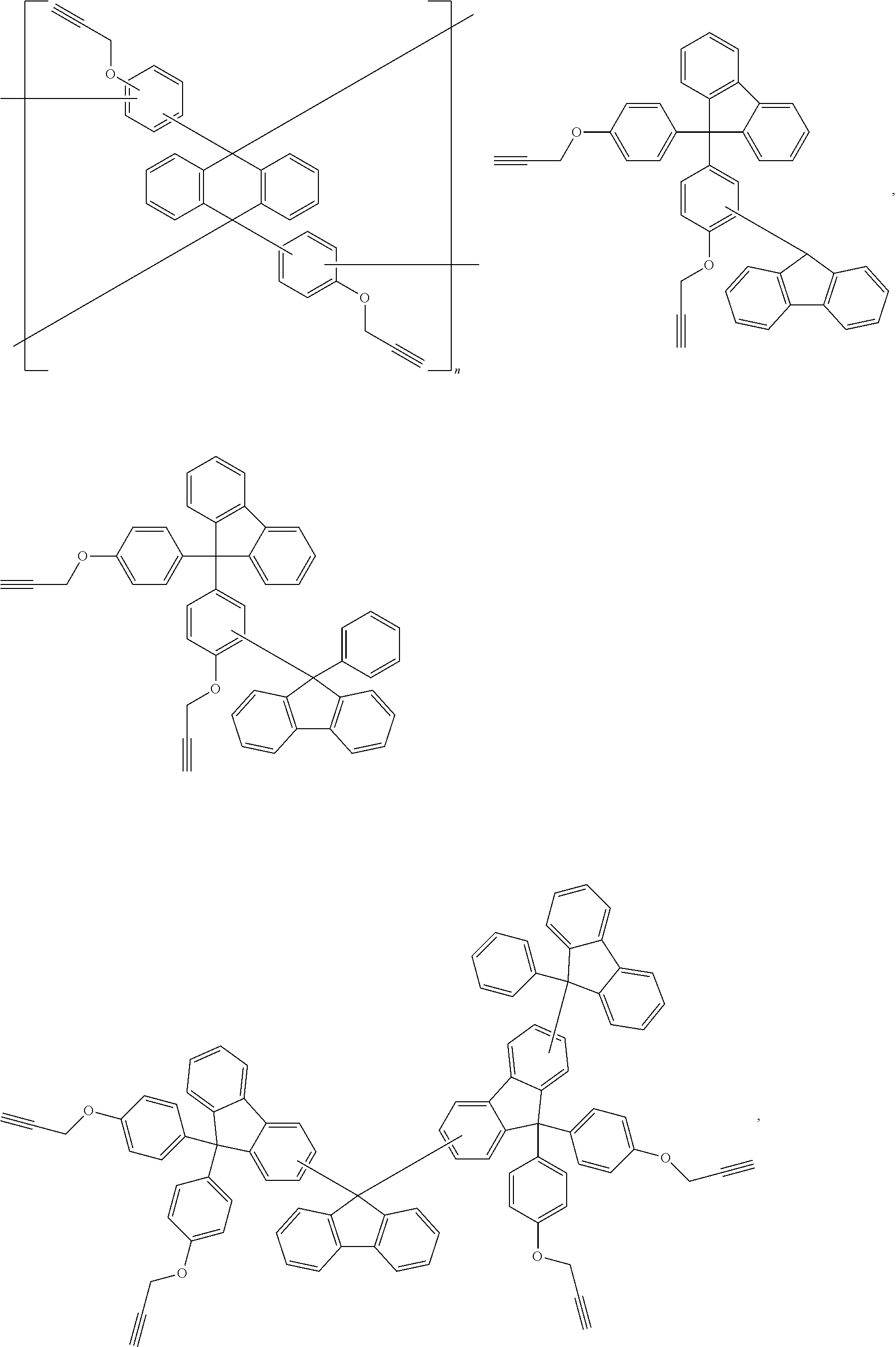

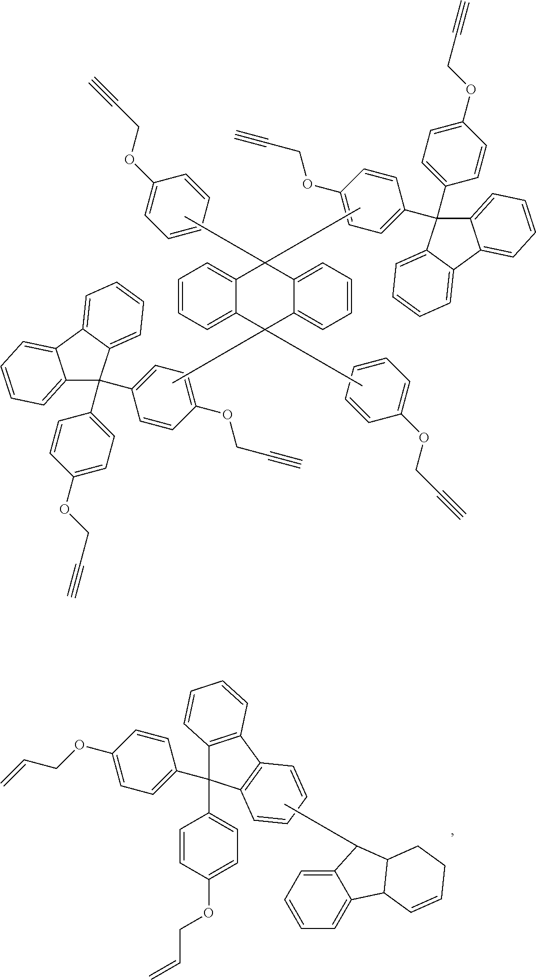

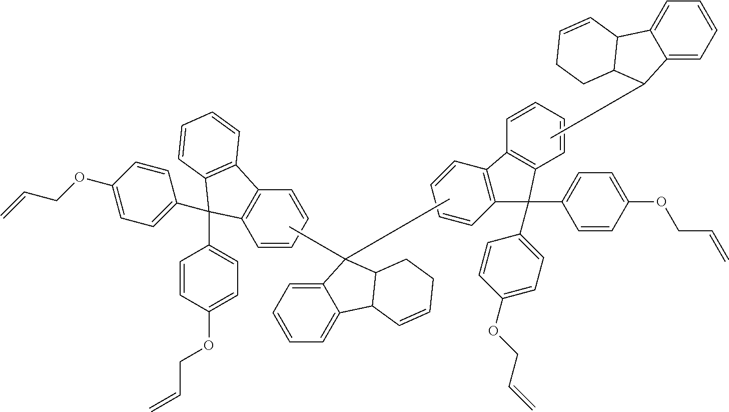

For example, the compound on the left below can be understood as a component (A) composed of two units represented by the formula (A-1). In the structure of one formula (A-1), R₂₁ indicated by a solid line arrow is a single bond bonded to another structural unit, Ar₂₁ is 9,9-diphenylfluorene, p₁₁=2, and q₁₁=r₁₁=s₁₁=0. Any of the group enclosed in parentheses to which p₁₁ attached as a subscript is bonded to Ar₂₁. In the structure of another formula (A-1), R₂₁ indicated by the broken line arrow is hydrogen, Ar₂₁ is 9,9-diphenylfluorene, p₁₁=2, and q₁₁=r₁₁=s₁₁=0. Any of the group enclosed in parentheses to which p₁₁ is attached is bonded to Ar₂₁.

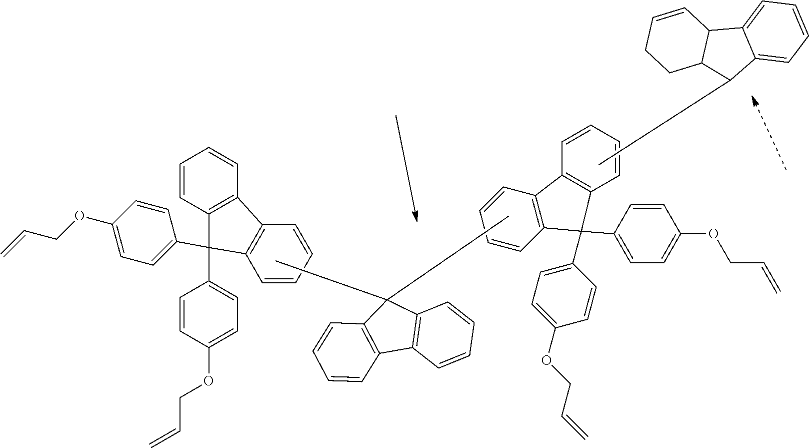

As a further preferable aspect of the present invention, the unit (A1-1) is a unit (A1-1-1). The structural unit (A1-1-1) is represented by the formula (A1-1-1).

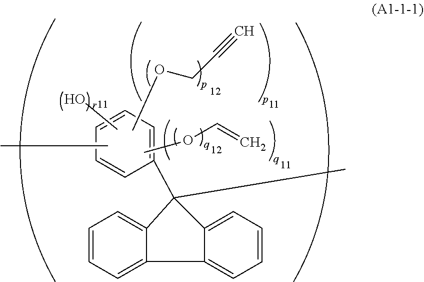

The definitions and preferred examples of p₁₁, p₁₂, q₁₁, q₁₂, r₁₁ and s₁₁ are each independently the same as above. Provided that, 1≤p₁₁+q₁₁+r₁₁≤4 is satisfied.

The formula (A1-2) is as follows.

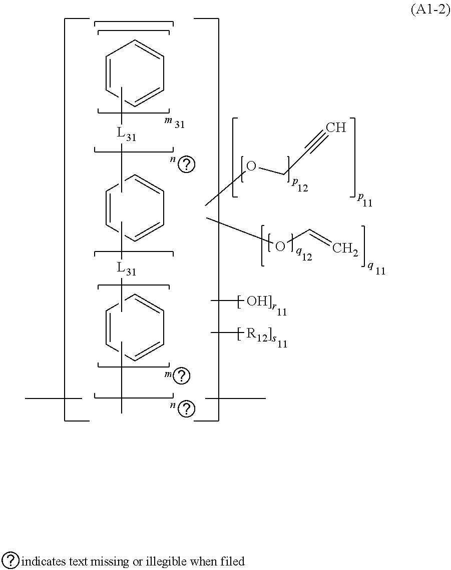

where,
L₃₁ and L₃₂ are each independently a single bond or phenylene (preferably a single bond).
n₃₁, n₃₂, m₃₁ and m₃₂ are each independently 0 to 6 (preferably 0, 1, 2 or 3). n₃₁+n₃₂=5 or 6 is a preferred embodiment.
When L₃₁ is a single bond, m₃₁=1. When L₃₂ is a single bond, m₃₂=1.

The definitions and preferred examples of R₁₂, p₁₁, p₁₂, q₁₁, q₁₂, r₁ and s₁₁ are each independently the same as above.

Examples of the component (A) having the structure of the formula (A1-2) include the following.

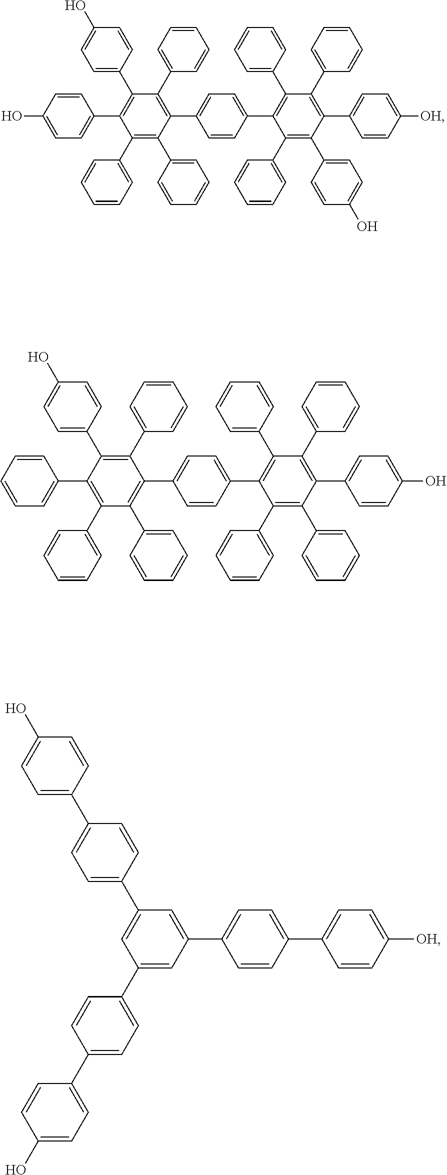 [SMILES: Oc1ccc(-c2c(-c3ccccc3)c(-c3ccccc3)c(-c3ccc(-c4c(-c5ccccc5)c(-c5ccccc5)c(-c5ccc(O)cc5)c(-c5ccc(O)cc5)c4-c4ccccc4)cc3)c(-c3ccccc3)c2-c2ccc(O)cc2)cc1 ; Oc1ccc(-c2c(-c3ccccc3)c(-c3ccccc3)c(-c3ccc(-c4c(-c5ccccc5)c(-c5ccccc5)c(-c5ccccc5)c(-c5ccc(O)cc5)c4-c4ccccc4)cc3)c(-c3ccccc3)c2-c2ccccc2)cc1 ; Oc1ccc(-c2ccc(-c3cc(-c4ccc(-c5ccc(O)cc5)cc4)cc(-c4ccc(-c5ccc(O)cc5)cc4)c3)cc2)cc1]

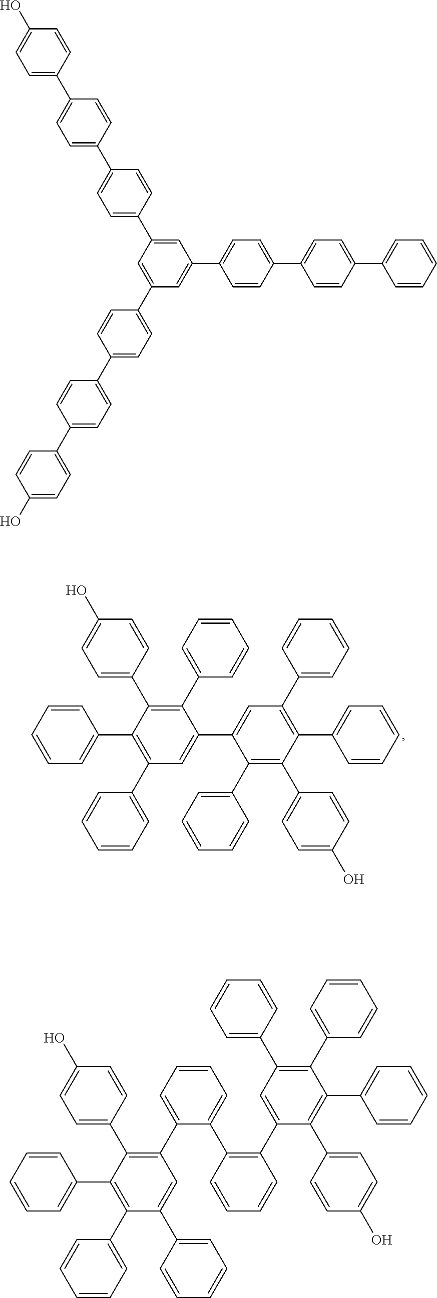 [SMILES: Oc1ccc(-c2ccc(-c3ccc(-c4cc(-c5ccc(-c6ccc(-c7ccccc7)cc6)cc5)cc(-c5ccc(-c6ccc(-c7ccc(O)cc7)cc6)cc5)c4)cc3)cc2)cc1 ; Oc1ccc(-c2c(-c3ccccc3)c(-c3ccccc3)cc(-c3cc(-c4ccccc4)c(-c4ccccc4)c(-c4ccc(O)cc4)c3-c3ccccc3)c2-c2ccccc2)cc1 ; Oc1ccc(-c2c(-c3ccccc3-c3ccccc3-c3cc(-c4ccccc4)c(-c4ccccc4)c(-c4ccccc4)c3-c3ccc(O)cc3)cc(-c3ccccc3)c(-c3ccccc3)c2-c2ccccc2)cc1]

The formula (A1-3) is as follows.

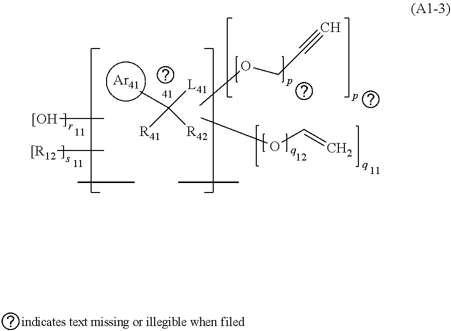

where,
Ar₄₁ is a C₆₋₅₀ aromatic hydrocarbon group (preferably phenyl).
R₄₁ and R₄₂ are each independently C₁₋₁₀ alkyl (preferably linear C₁₋₆ alkyl), and R₄₁ and R₄₂ can be bonded to each other to form a ring (preferably a saturated hydrocarbon ring).
The carbon atom at the position of *41 is a quaternary carbon atom.
L₄₁ is C₆₋₅₀ arylene or a single bond bonded to another structural unit (preferably phenylene or a single bond bonded to another structural unit; more preferably a single bond bonded to another structural unit).
The definitions and preferred examples of R₁₂, p₁₁, p₁₂, q₁₁, q₁₂, r₁ and s₁₁ are the same as above.

Examples of the component (A) having the formula (A1-3) include the following.

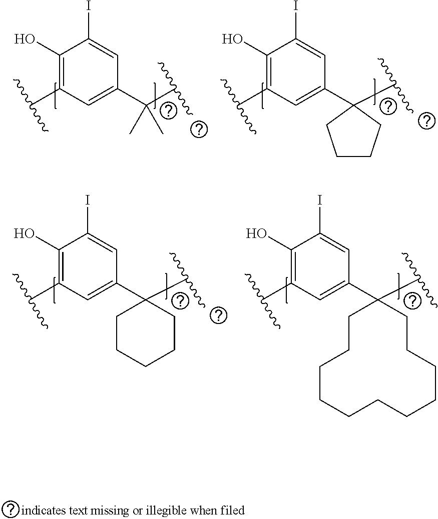

The formula (A1-4) is as follows.

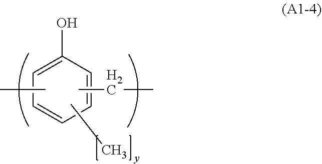

where,
y is 0 to 2 (preferably 0.5 to 1.5; more preferably 0 or 1).

The formula (A1-4) is preferably the formula (Q-1a), (Q-1b), (Q-1c) or (Q-1d).

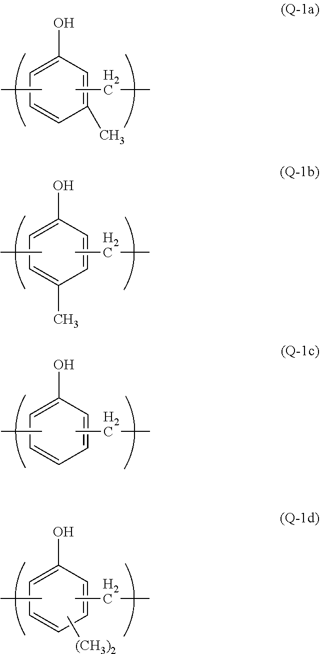

In a preferred embodiment, the component (A) is a polymer (hereinafter, sometimes referred to as the polymer Q) comprising units selected from the group consisting of formulae (Q-1a), (Q-1b), (Q-1c) and (Q-1d). The polymer Q more preferably consists only of units selected from the group consisting of the formulae (Q-1a), (Q-1b), (Q-1c) and (Q-1d), and further preferably consists only of the repeating units of the formulae (Q-1a) and (Q-1 b).

It is preferable that, in the polymer Q, the number of repeating units Nqa of (Q-1a), the number of repeating units Nqb of (Q-1b), the number of repeating units Nqc of (Q-1c) and the number of repeating units Nqd of (Q-1d) satisfy the following formulae:

$$30 \% \leq Nqa / ( Nqa + Nqb + Nqc + Nqd ) \leq 100 \% ; \\ 0 \% \leq Nqb / ( Nqa + Nqb + Nqc + Nqd ) \leq 70 \% ; \\ 0 \% \leq Nqc / ( Nqa + Nqb + Nqc + Nqd ) \leq 50 \% ; and \\ 0 \% \leq Nqd / ( Nqd + Nqb + Nqc + Nqd ) \leq 70 \% .$$

Nqa/(Nqa+Nqb+Nqc+Nqd) is more preferably 30 to 90% (further preferably 40 to 80%; further more preferably 50 to 70%).
Nqb/(Nqa+Nqb+Nqc+Nqd) is more preferably 10 to 60% (further preferably 20 to 50%; further more preferably 30 to 50%).
Nqc/(Nqa+Nqb+Nqc+Nqd) is more preferably 0 to 40% (further preferably 10 to 30%). It is also a preferable embodiment that Nqc/(Nqa+Nqb+Nqc+Nqd) is 0%.
Nqd/(Nqa+Nqb+Nqc+Nqd) is more preferably 0 to 40% (further preferably 10 to 30%). It is also a preferable embodiment that Nqd/(Nqa+Nqb+Nqc+Nqd) is 0%. In the polymer Q, an aspect in which one of the repeating units of the formulae (Q-1c) and (Q-1d) is present and the other is not present is also preferable.

The mass average molecular weight (hereinafter, sometimes referred to as Mw) of the polymer Q is preferably 400 to 100,000 (more preferably 5,000 to 75,000; further preferably 6,000 to 50,000; further more preferably 9,000 to 20,000). In the present invention, Mw can be measured by gel permeation chromatography (GPC). In this measurement, it is a preferable example to use a GPC column at 40° C., an elution solvent tetrahydrofuran at 0.6 mL/min, and monodispersed polystyrene as a standard. The same applies to the following.

The component (A) is preferably a polymer. In a preferable embodiment of the present invention, when the component (A) is a polymer comprising a unit represented by the formula (A1-1), (A1-2) or (A1-3), the aldehyde derivative used when the component (A) is synthesized is preferably 0 to 30 mol % (more preferably 0 to 15 mol %; further preferably 0 to 5 mol %; further more preferably 0 mol %) based on the sum of all the elements used in the synthesis. Examples of the aldehyde derivative include formaldehyde.

It is a preferable embodiment of the present invention to use a ketone derivative instead of using an aldehyde derivative.

The polymer thus synthesized can have the characteristic that the main chain contains no or few secondary carbon atoms and tertiary carbon atoms. In a preferred embodiment of the present invention, the polymer contains substantially neither secondary nor tertiary carbon atoms in its main chain. Although not to be bound by theory, while the polymer ensuring the solubility due to this, heat resistance of the formed film can be expected to be improved. However, it is permissible to include secondary carbon atoms and tertiary carbon atoms at the ends of the polymer like the terminal modification.

Although not to be bound by theory, containing the component (A) makes it possible to have the film formed from the present composition harder and increase the etching resistance. Examples of such a component (A) include those in which the unit (A1) is the formula (A1-1), the formula (A1-2) and/or the formula (A1-3).

Although not to be bound by theory, containing the component (A) makes it possible to increase the viscosity of the present composition and increase the crack resistance of the film formed from the present composition. Examples of such a component (A) include one in which the unit (A1) is the formula (A1-4).

As one embodiment of the present invention, the molecular weight of the component (A) is preferably 400 to 100,000 (more preferably 1,000 to 5,000; further preferably 2,000 to 20,000). When the component (A) is a polymer, Mw is used as the molecular weight.

In the component (A), the molecular weight of the substance comprising the unit represented by the formula (A1-1), (A1-2) or (A1-3) is preferably 500 to 6,000 (more preferably 500 to 4,000; further preferably 1,500 to 3,000).

The component (A) can be one or more kinds. The component (A) preferably comprises the structure of the formula (A1-1), (A1-2) or (A1-3), and more preferably comprises the structure of the formula (A1-1).

When the component (A) is two or more kinds, the component (A) preferably comprises a combination of a compound having the structure of the formula (A1-1), (A1-2) or (A1-3) with the polymer Q, and more preferably comprises a combination of a compound having the structure of formula (A1-1) with the polymer Q.

The content of the component (A) is preferably 3 to 40 mass % (more preferably 10 to 35 mass %; further preferably 20 to 30 mass %) based on the composition,

### Solvent (B)

The composition according to the present invention comprises the solvent (B). The solvent (B) comprises an organic solvent (B1) and an organic solvent (B2) having a dielectric constant of 20.0 to 90.0. The dielectric constant of the organic solvent (B1) is preferably not 20.0 to 90.0; more preferably less than 20; further preferably 1 to 19; further more preferably. 5 to 15.

The dielectric constant of the organic solvent (B2) is preferably 25 to 50 (more preferably 30 to 40; further preferably 35 to 40).

The dielectric constant can be measured by the LCR meter method. For example, it can be calculated at a measurement frequency of 1 MHz and 20° C. using the LCR meter HP4284A (Agilent Technology).

As the solvent (B) contains the solvent (B2) having a high dielectric constant, a cured film having a high hardness can be obtained even with a thick film and low-temperature heating. Although not to be bound by theory, it can be thought that due to the presence of the solvent (B2), the curing reaction is promoted. For example, in the curing reaction, it can be thought that an intermediate is likely to be generated, the intermediate is stabilized, or the movable range of the component (A) is likely to be widened.

The boiling point of the organic solvent (B2) at 1 atm is preferably 100 to 400° C. (more preferably 150 to 250° C.; further preferably 190 to 250° C.).

δp/(δD+δp+δH) of the organic solvent (B2) is preferably 20 to 50% (more preferably 20 to 40%; further preferably 30 to 40%). δD, δp and δH are the three parameters of the Hansen solubility parameters. Hansen solubility parameters can be obtained by known methods. For example, the method described in Non-Patent Document 1 can be used.

Examples of the organic solvent (B2), and their boiling point, dielectric constant and δp/(δD+δp+δH) are listed in the table below.

TABLE 1

| | Boiling point | Dielectric | |
|---|---|---|---|
| | ° C. | constant | δp/(δd + δp + δh) |
| γ-valerolactone | 207.0 | 36.47 | 33.1% |
| N-methyl-pyrrolidone | 202.0 | 32.00 | 32.8% |
| dipropylene glycol | 230.5 | 32.10 | 37.2% |
| γ-butyrolactone | 204.0 | 39.00 | 38.8% |
| methanol | 64.7 | 33 | 24.7% |
| ethanol | 78.3 | 24 | 20.0% |
| diethylene glycol | 244.8 | 32 | 28.8% |
| propylene carbonate | 242.0 | 66-70 | 42.7% |
| acetone | 56.0 | 21 | 31.7% |
| acetonitrile | 82.0 | 38 | 45.6% |

The organic solvent (B1) is not particularly limited excluding any solvent that is the organic solvent (B2). The organic solvent (B1) is a hydrocarbon solvent, an ether solvent, an ester solvent, an alcohol solvent, a ketone solvent, or a mixture thereof.

Examples of the organic solvent (B1) include, for example, propylene glycol 1-monomethyl ether 2-acetate (PGMEA), propylene glycol monomethyl ether (PGME), anisole, ethyl lactate (EL), n-butyl acetate (nBA), n-butyl ether (DBE), or a mixture thereof. The organic solvent (B1) is preferably PGMEA, PGME or a mixture thereof (more preferably a mixture of PGMEA and PGME). When two kinds are mixed, the mass ratio thereof is preferably 95:5 to 5:95 (more preferably 90:10 to 10 90; further preferably 80:20 to 20:80).

The solvent (B) can contain a solvent other than the organic solvent (B1) and the organic solvent (B2), for example, water. It is also a preferable embodiment that the solvent (B) substantially contain no water in relation to other layers and films. The amount of water in the entire solvent (B) is preferably 0.1 mass % or less (more preferably 0.01 mass % or less; further preferably 0.001 mass % or less). It is also a preferable embodiment that the solvent (B) contains no water (0.000 mass %).

The content of the solvent (B) is preferably 50 to 97 mass % (more preferably 60 to 90 mass %; further preferably 65 to 80 mass %) based on the composition.

The content of the organic solvent (B1) is preferably 70 to 99 mass % (more preferably 80 to 99 mass %; further preferably 90 to 98 mass %) based on the solvent (B).

The content of the organic solvent (B2) is preferably 1 to 20 mass % (more preferably 1 to 15 mass %; further preferably 2 to 10 mass %) based on the solvent (B).

### Component (C) Comprising a Cross-Linking Group

The composition according to the present invention can further comprise a component (C) comprising a cross-linking group. The component (C) is a component different from the component (A) represented by the formulae (A1-1), (A1-2), (A1-3) and (A1-4). This means, when these components fall under the definition of the component (A), even if having a cross-linking group, they are the component (A) and not the component (C).

Examples of the cross-linking group include hydroxy, methoxy, acryloyloxy, methacryloyloxy, ethenyl, ethenyloxy, 2-propenyl, 1-propenyl and the like.

Although not to be bound by theory, it can be thought that the component (C) contributes to the improvement of density during the formation of the cured film, can eliminate intermixing with the upper layer film (for example, a resist film) to reduce the diffusion of the low molecular weight component into the upper layer film.

The component (C) comprising a cross-linking group is preferably represented by the formula (Cl).

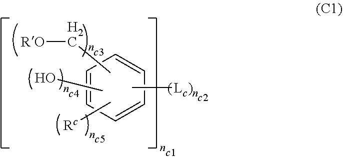

wherein,
n_{c1} is 1, 2, 3 or 4 (preferably 1, 2 or 3; more preferably 1 or 2).
n_{c2} is 0 when n_{c1} is 1, and 1 when n_{c1} is 2 or more.
n_{c3} is 0, 1 or 2 (preferably 2).
n_{c4} is 1 or 2 (preferably 1). n_{c5} is 0 or 1 (preferably 0).
L_{c} is a single bond or a C₁₋₃₀ hydrocarbon group (preferably a single bond, C₁₋₂₀ alkylene, C₆₋₃₀ arylene; more preferably a single bond).

R^{c} is each independently C₁₋₆ alkyl or C₆₋₁₀ aryl, and methylene in the alkyl is replaced or not replaced with —O—. R^{c} is preferably methyl or phenyl.
R′ is hydrogen or methyl (preferably methyl).

Examples of the component (C) include the following.

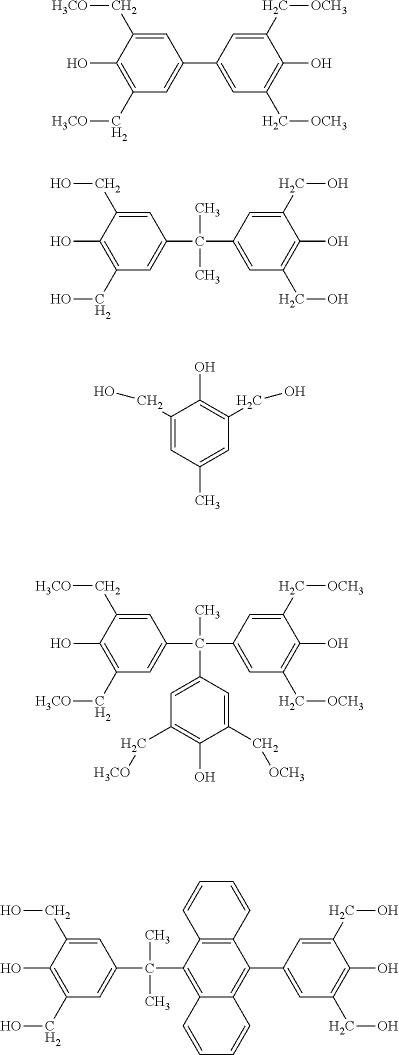 [SMILES: COCc1cc(-c2cc(COC)c(O)c(COC)c2)cc(COC)c1O ; CC(C)(c1cc(CO)c(O)c(CO)c1)c1cc(CO)c(O)c(CO)c1 ; Cc1cc(CO)c(O)c(CO)c1 ; COCc1cc(C(C)(c2cc(COC)c(O)c(COC)c2)c2cc(COC)c(O)c(COC)c2)cc(COC)c1O ; CC(C)(c1cc(CO)c(O)c(CO)c1)c1c2ccccc2c(-c2cc(CO)c(O)c(CO)c2)c2ccccc12]

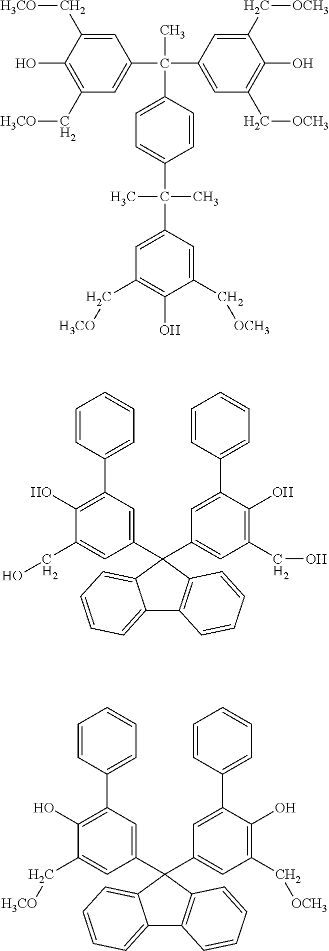 [SMILES: COCc1cc(C(C)(C)c2ccc(C(C)(c3cc(COC)c(O)c(COC)c3)c3cc(COC)c(O)c(COC)c3)cc2)cc(COC)c1O ; OCc1cc(C2(c3cc(CO)c(O)c(-c4ccccc4)c3)c3ccccc3-c3ccccc32)cc(-c2ccccc2)c1O ; COCc1cc(C2(c3cc(COC)c(O)c(-c4ccccc4)c3)c3ccccc3-c3ccccc32)cc(-c2ccccc2)c1O]

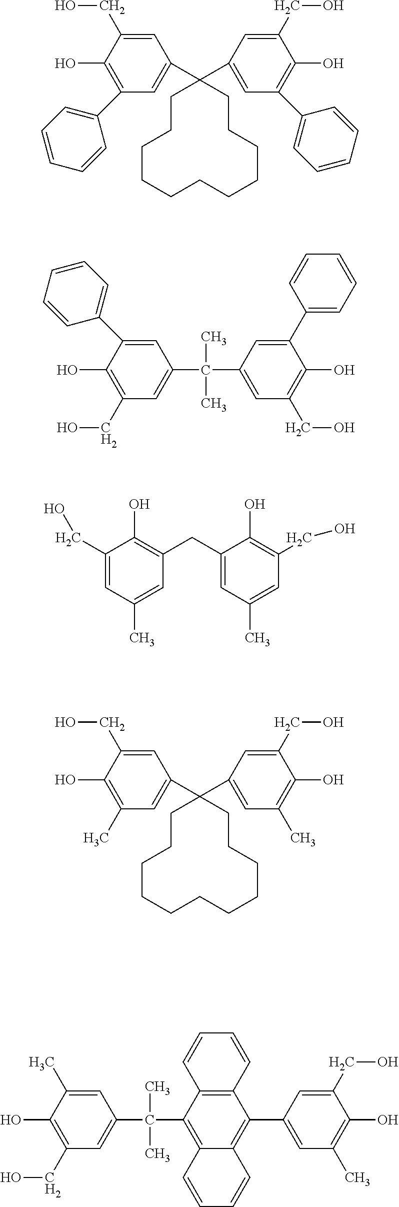 [SMILES: OCc1cc(C2(c3cc(CO)c(O)c(-c4ccccc4)c3)CCCCCCCCCCC2)cc(-c2ccccc2)c1O ; CC(C)(c1cc(CO)c(O)c(-c2ccccc2)c1)c1cc(CO)c(O)c(-c2ccccc2)c1 ; Cc1cc(CO)c(O)c(Cc2cc(C)cc(CO)c2O)c1 ; Cc1cc(C2(c3cc(C)c(O)c(CO)c3)CCCCCCCCCCC2)cc(CO)c1O ; Cc1cc(-c2c3ccccc3c(C(C)(C)c3cc(C)c(O)c(CO)c3)c3ccccc23)cc(CO)c1O]

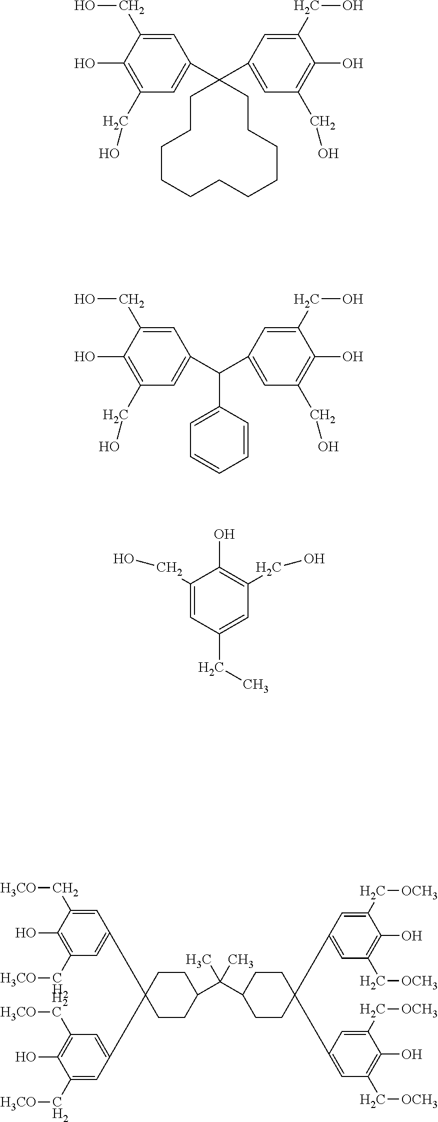 [SMILES: OCc1cc(C2(c3cc(CO)c(O)c(CO)c3)CCCCCCCCCCC2)cc(CO)c1O ; OCc1cc(C(c2ccccc2)c2cc(CO)c(O)c(CO)c2)cc(CO)c1O ; CCc1cc(CO)c(O)c(CO)c1 ; COCc1cc(C2(c3cc(COC)c(O)c(COC)c3)CCC(C(C)(C)C3CCC(c4cc(COC)c(O)c(COC)c4)(c4cc(COC)c(O)c(COC)c4)CC3)CC2)cc(COC)c1O]

Content of the component (C) is preferably 0 to 30 mass % (more preferably 1 to 20 mass %; further preferably 5 to 15 mass %) based on the total content of the component (A) and the component (E) (when the component (E) is not contained, it means the content of the component (A). The same applies to the following).

### Acid Generator (D)

The composition according to the present invention can further comprise an acid generator (D). The component (D) is useful from the viewpoint of improving heat resistance (promotion of the cross-linking reaction).

As the component (D), a thermal acid generator (TAG) capable of generating a strong acid by heating can be mentioned. A preferred thermal acid generator is one that activates at a temperature above 80° C. Examples of the thermal acid generator include metal-free sulfonium salts and iodonium salts, such as triarylsulfonium, dialkylarylsulfonium and diarylalkylsulfonium salts of strong non-nucleophilic acids; alkylaryliodonium, diaryliodonium salts of strong non-nucleophilic acids; and ammonium, alkylammonium, dialkylammonium, trialkylammonium, tetraalkyl-ammonium salts of strong non-nucleophilic acids. Covalent thermal acid generators are also considered as useful additives, and examples thereof include 2-nitrobenzyl esters of alkyl or aryl sulfonic acids, and other esters of sulfonic acids that are thermally decomposed to give free sulfonic acids. Examples thereof include diaryliodonium perfluoroalkyl sulfonate, diaryliodonium tris(fluoroalkylsulfonyl) methide, diaryliodonium bis(fluoroalkylsulfonyl) methide, diaryliodonium bis(fluoroalkylsulfonyl)imide, and diaryliodonium quaternary ammonium perfluoroalkyl sulfonate. Examples of the labile ester include 2-nitrobenzyl tosylate, 2,4-dinitrobenzyl tosylate, 2,6-dinitrobenzyl tosylate, 4-nitrobenzyl tosylate; benzene sulfonates such as 2-trifluoromethyl-6-nitrobenzyl 4-chlorobenzene sulfonate and 2-trifluoromethyl-6-nitrobenzyl 4-nitrobenzene sulfonate; phenolic sulfonate esters such as phenyl 4-methoxybenzene sulfonate; quaternary ammonium tris(fluoroalkylsulfonyl) methides; quaternary alkylammonium bis(fluoroalkylsulfonyl)imides; and alkylammonium salts of organic acids, for example, triethylammonium salt of 10-camphorsulfonic acid. Various aromatic (anthracene, naphthalene or benzene derivatives) sulfonic acid amine salts including those disclosed in U.S. Pat. Nos. 3,474,054 A, 4,200,729 A, 4,251,665 A and 5,187,019 A can also be used as the TAG.

The content of the component (D) is preferably 0 to 5 mass % (more preferably 0.1 to 3 mass %; further preferably 0.5 to 2 mass %) based on the total content of the component (A) and the component (E).

### Polymer (E)

The composition according to the present invention can further comprise a polymer (E). Although describing for clarity, the polymer (E) differs from other components in the composition. For example, it is different from the component (A) and the component (F). The polymer (E) is not particularly limited, and examples thereof include styrene, hydroxystyrene, or a copolymer of any of these.

The content of the polymer (E) is preferably 0 to 300 mass % (more preferably 0.1 to 50 mass %; further preferably 0.1 to 10 mass %) based on the component (A). It is also a preferred embodiment of the present invention that the polymer (E) is not contained (0.0 mass %).

The Mw of the polymer (E) is preferably 1,000 to 100,000 (more preferably 2,000 to 10,000).

### High Carbon Material (F)

The composition according to the present invention can further comprise a high carbon material (F). By adding the component (F), the composition as a whole can satisfy the formula (X) described later, and a cured film having good etching resistance can be formed. Although describing for clarity, the component (F) is different from the other components in the composition. For example, the component (F) is different from the component (A) that contains the structures represented by the formulae (A1-1), (A1-2), (A1-3) and (A1-4). For example, the component (F) is different from the component (C) represented by the formula (Cl). The component (F) can be either low molecular weight or high molecular weight, and preferably consists only of carbon (C), oxygen (O) and hydrogen (H), and more preferably consists only of carbon (C) and hydrogen (H). Although not to be bound by theory, as the composition of the present invention comprises the component (F), a thick film having better etching resistance can be obtained.

The high carbon material (F) is preferably represented by the formula (F1).

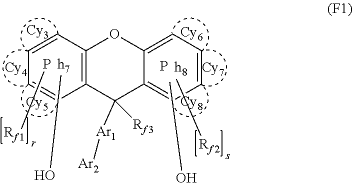

wherein,
Ar₁ is a single bond, C₁₋₆ alkyl, C₆₋₁₂ cycloalkyl or C₆₋₁₄ aryl (preferably a single bond, C₁₋₆ alkyl or phenyl; more preferably a single bond, linear C₃ alkyl, linear C₆ alkyl, tertiary butyl or phenyl; further preferably a single bond or phenyl).
Ar₂ is C₁₋₆ alkyl, C₆₋₁₂ cycloalkyl or C₆₋₁₄ aryl (preferably isopropyl, tertiary butyl, C₆ cycloalkyl, phenyl, naphthyl, phenanthryl or biphenyl; more preferably phenyl).
R_{f1} and R_{f2} are each independently C₁₋₆ alkyl, hydroxy, halogen, or cyano (preferably methyl, ethyl, propyl, isopropyl, tertiary butyl, hydroxy, fluorine, chlorine or cyano; more preferably methyl, hydroxy, fluorine or chlorine).
R_{f3} is hydrogen, C₁₋₆ alkyl or C₆₋₁₄ aryl (preferably hydrogen, C₁₋₆ alkyl or phenyl; more preferably hydrogen, methyl, ethyl, linear C₅ alkyl, tertiary butyl or phenyl; further preferably hydrogen or phenyl; further more preferably hydrogen).
Provided that, when Ar₂ is C₁₋₆ alkyl or C₆₋₁₄ aryl and R_{f3} is C₁₋₆ alkyl or C₆₋₁₄ aryl, Ar₂ and R_{f3} can be bonded to each other to form a ring.
r and s are each independently 0, 1, 2, 3, 4 or 5 (preferably 0 or 1; more preferably 0).
At least one of the C_{y3}, C_{y4} and C_{y5} rings surrounded by a broken line is an aromatic hydrocarbon ring fused with the adjacent aromatic hydrocarbon ring Ph₇, and the number of carbon atoms in the aromatic hydrocarbon ring is preferably C₁₀₋₁₄, more preferably C₁₀, including the carbons of the aromatic hydrocarbon ring Ph₇.

At least one of the C_{y6}, C_{y7} and C_{y5} rings surrounded by a broken line is an aromatic hydrocarbon ring fused with the adjacent aromatic hydrocarbon ring Pₕ₈, and the number of carbon atoms in the aromatic hydrocarbon ring is preferably C₁₀₋₁₄, more preferably C₁₀, including the carbons of the aromatic hydrocarbon ring Pₕ₈.

In the formula (F1), the bonding positions of R_{f1}, R_{f2} and OH are not limited.

For example, the following compound can have the following structure in the formula (F1). The aromatic hydrocarbon ring Ph₇ and the aromatic hydrocarbon ring C_{y5} are fused to form a naphthyl ring, and OH is bonded to the aromatic hydrocarbon ring C_{y5}. Ar₁ is a single bond, Ar₂ and R_{f3} are phenyl, and Ar₂ and R_{f3} are bonded to form a hydrocarbon ring (fluorene).

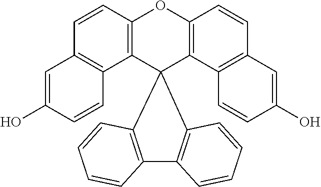 [SMILES: Oc1ccc2c3c(ccc2c1)Oc1ccc2cc(O)ccc2c1C31c2ccccc2-c2ccccc21]

Exemplified embodiments of the high carbon material represented by the formula (F1) include the following.

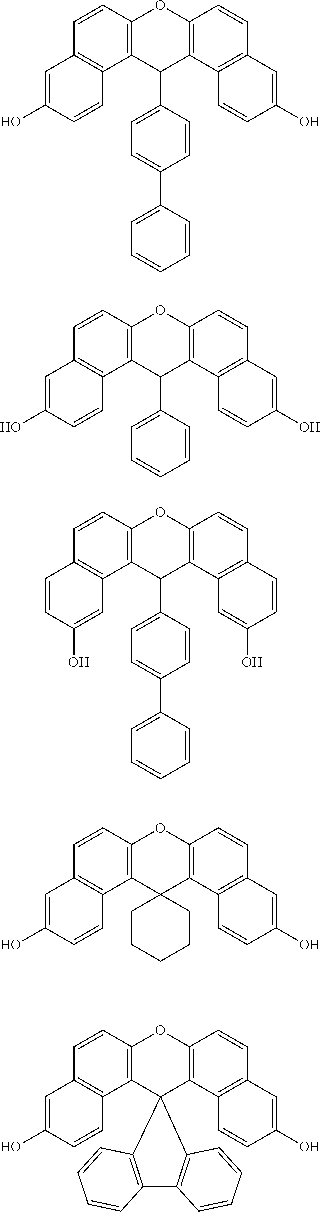

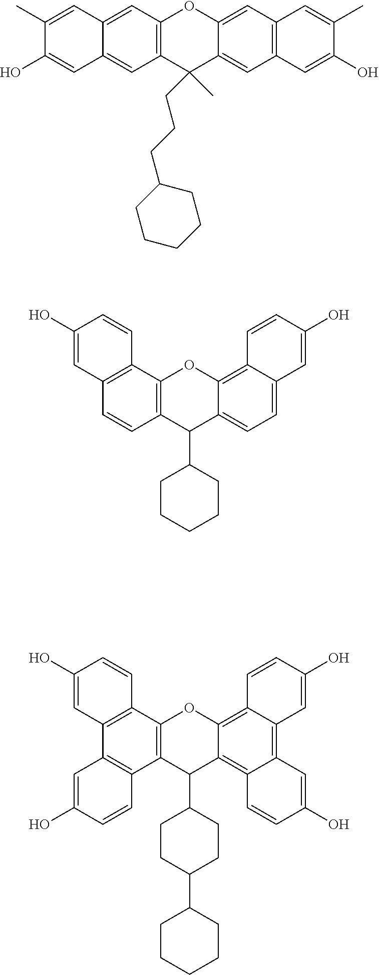 [SMILES: Cc1cc2cc3c(cc2cc1O)C(C)(CCCC1CCCCC1)c1cc2cc(O)c(C)cc2cc1O3 ; Oc1ccc2c3c(ccc2c1)C(C1CCCCC1)c1ccc2cc(O)ccc2c1O3 ; Oc1ccc2c3c(c4ccc(O)cc4c2c1)C(C1CCC(C2CCCCC2)CC1)c1c(c2ccc(O)cc2c2cc(O)ccc12)O3]

The content of the component (F) is preferably 0 to 200 mass % (more preferably 0 to 75 mass %; further preferably 1 to 50 mass %; further more preferably 15 to 30 mass %) based on the total content of the component (A) and the component (E). It is also a preferred aspect of the present invention that the component (F) is not contained (0.0 mass %).

### Surfactant (G)

The composition according to the present invention can further comprise a surfactant (G). By containing the surfactant, coating properties can be improved.

The surfactant that can be used in the present invention includes (I) an anionic surfactant, (II) a cationic surfactant or (Ill) a nonionic surfactant, and more particularly, (I) alkyl sulfonate, alkylbenzene sulfonic acid and alkylbenzene sulfonate, (II) lauryl pyridinium chloride and lauryl methyl ammonium chloride, and (Ill) polyoxyethylene octyl ether, polyoxyethylene lauryl ether and polyoxy ethylene acetylenic glycol ether, and fluorine-containing surfactants, such as Fluorad (3M), Megaface (DIC), Surflon (AGC)), or organosiloxane surfactants (for example, KP341 (Shin-Etsu Chemical)) are preferred.

The content of the component (G) is preferably 0 to 20 mass % (more preferably 0 to 2 mass %; further preferably 0.01 to 1 mass %) based on the total content of the component (A) and the component (E).

### Additive (H)

The composition according to the present invention can further comprise an additive (H) other than the above-mentioned components. The additive (H) is preferably selected from the group consisting of acids, bases, radical generators, photopolymerization initiators, and substrate adhesion enhancers.

The content of the component (H) is preferably 0 to 10 mass % (more preferably 0.001 to 10 mass %; further preferably 0.001 to 5 mass %) based on the total content of the component (A) and the component (E). It is also a preferable embodiment of the present invention that the component (H) is not contained (0%).

It is preferred that the composition according to the present invention has a high carbon content of the solid components contained therein. That is, when one or more solid components contained in the composition (total of each solid component in the composition) satisfy the following formula (X), the carbon content is high and therefore preferable. For example, when the present thick film-forming composition has as solid components three kinds, which are a hydrocarbon-containing compound (A), a polymer (E) and a surfactant (G), it is preferable that the formula (X) is satisfied as a whole of the solid components.

It can be calculated using the molar ratio.

$$1.5 \leq \{ total number of atoms / ( number of C - number of O ) \} \leq 3.5 \qquad Formula ( X )$$

$$wherein , \\ the number of C is the number of carbon atoms , and \\ the number of O is the number of oxygen atoms . \qquad Formula {( X )}^{′}$$

$$Preferably , the formula ( X ) is the formula {( X )}^{′} or the formula {( X )}^{″} . \\ 1.5 \leq \{ total number of atoms / ( number of C - number of O ) \} \leq 2.4$$

$$1.8 \leq \qquad Formula {( X )}^{″}$$

$$\{ total number of atoms / ( number of C - number of O ) \} \leq 2.4$$

### [Method for Manufacturing a Cured Film]

The method for manufacturing a cured film according to the present invention comprises the following processes:
(1) applying the above-mentioned composition according to the present invention above a substrate to form a hydrocarbon-containing film; and
(2) heating the hydrocarbon-containing film.

The film thickness of the cured film is 0.5 to 10 μm (preferably 1 to 8 μm; more preferably 1.5 to 5 μm; further preferably 2 to 4 μm). Hereinafter, the numbers in parentheses indicate the order of the processes. For example, when the processes (1), (2), and (3) are described, the order of the processes is as described above.

### Process (1)

Examples of the substrate include a semiconductor wafer, a glass substrate for a liquid crystal display device, a glass substrate for an organic EL display device, a glass substrate for a plasma display, a substrate for an optical disk, a substrate for a magnetic disk, a substrate for an optical magnetic disk, a glass substrate for a photomask, a substrate for a solar cell and the like. The substrate can be a flat substrate, or can be a non-flat substrate to which processing or the like has been applied, but is preferably a non-flat substrate. The substrate can be composed by laminating a plurality of layers.

Preferably, the surface of the substrate is a semiconductor. The semiconductor can be composed of an oxide, a nitride, a metal, or a combination of any of these. Preferably, the surface of the substrate is selected from the group consisting of Si, Ge, SiGe, Si₃N₄, TaN, SiO₂, TiO₂, Al₂O₃, SiON, HfO₂, Ta₂O₅, HfSiO₄, Y₂O₃, GaN, TiN, TaN, Si₃N₄, NbN, Cu, Ta, W, Hf and Al.

The composition according to the present invention is applied above a substrate by an appropriate method. In the present invention, the “above” includes the case where a layer is formed in contact with and above a substrate and the case where a layer is formed above a substrate with another layer in contact with the layer. The application method is not particularly limited, and examples thereof include a coating method with a spinner and a coater, thereby forming a hydrocarbon-containing film.

### Process (2)

A cured film is manufactured by heating the hydrocarbon-containing film. The heating temperature in (2) is preferably lower than 340° C. (more preferably 70 to 330° C.). The temperature is that of heating atmosphere, for example, that of heating surface of a hot plate. The heating time is preferably 30 to 300 seconds (more preferably 60 to 240 seconds). It is also possible to perform the heating by separating into multiple steps (stepwise baking). Preferably, the heating in (2) is performed in two stages, the first heating is performed at 70 to 330° C. and the second heating is performed at 200 to 330° C. When the two-stage heating is performed, it is preferable that the first time is performed for 30 to 120 seconds and the second time is performed for 60 to 180 seconds. When performing the two-stage heating, it is preferable that the temperature of the second time is higher than that of the first time. When performing the two-stage heating, it is preferable that the time of the second time is longer than that of the first time.

Generally, by performing the heating at a high temperature, it is possible to promote the curing reaction and contribute to increasing the density of the cured film. Although not to be bound by theory, according to the present invention, high density of the cured film can be achieved without high temperature heating.

Air is suitable as the heating atmosphere. It is also possible to reduce the oxygen concentration in order to prevent the oxidation of the hydrocarbon-containing film. For example, the oxygen concentration can be set to 1,000 ppm or less (preferably 100 ppm or less) by injecting an inert gas (N₂, Ar, He or a mixture thereof) into the atmosphere.

The surface resistivity of the cured film is preferably 10⁹ to 10¹⁶⁰ω□ (Ohm square). This surface resistivity is more preferably 10¹² to 10¹⁶ω□; further preferably 10¹³ to 10¹⁶ω□. The cured film formed is not a conductive polymer film.

### [Methods for Manufacturing a Resist Film and a Resist Pattern]

A resist film can be manufactured above the cured film manufactured by the method according to the present invention. The method for manufacturing a resist film comprises the following processes: manufacturing a cured film by the above-mentioned method;
(3) applying a resist composition above the cured film; and
(4) heating the resist composition to form a resist film.

A resist pattern can also be manufactured from the resist film manufactured by the method according to the present invention. The method for manufacturing a resist pattern comprises the following processes:
manufacturing a resist film by the above-mentioned method;
(5) performing the exposure to the resist film; and
(6) developing the resist film.

### Processes (3) and (4)

A resist composition is applied above the cured film by an appropriate method. The application method is not particularly limited, and examples thereof include a coating method with a spinner and a coater. After application, a resist film is formed by heating. The heating in (4) is performed by, for example, a hot plate. The heating temperature is preferably 100 to 250° C. The temperature is that of heating atmosphere, for example, that of heating surface of a hot plate. The heating time is preferably 30 to 300 seconds (more preferably 60 to 180 seconds). Heating is preferably performed in an air or nitrogen gas atmosphere.

The thickness of the resist film is selected according to the purpose. It is also possible to increase the thickness of the resist layer to more than 1 μm.

### Process (5)

The exposure to the resist film is performed through a predetermined mask. The wavelength of the light used for the exposure is not particularly limited, but it is preferable to expose with light having a wavelength of 190 to 440 nm. In particular, KrF excimer laser (wavelength: 248 nm), ArF excimer laser (wavelength: 193 nm), i-line (wavelength: 365 nm), h-line (wavelength: 405 nm), g-line (wavelength: 436 nm) and the like can be used. The wavelength is more preferably 240 to 440 nm, further preferably 360 to 440 nm, and further more preferably 365 nm. As to the wavelength, range of ±1% is accepted.

After exposure, post exposure bake (hereinafter sometimes referred to as PEB) can be optionally performed. The post exposure bake is performed, for example, by a hot plate. The temperature of the post exposure bake is preferably 80 to 160° C. (more preferably 105 to 115° C.), and the heating time thereof is 30 to 600 seconds (preferably 60 to 200 seconds). Heating is preferably performed in an air or nitrogen gas atmosphere.

### Process (6)

After exposure (PEB, if necessary), development is performed using a developer to manufacture a resist pattern. As the developing method, methods used for developing a photoresist, such as a paddle developing method, an immersion developing method, or a swinging immersion developing method, can be used. As the developer, aqueous solution containing inorganic alkalis, such as sodium hydroxide, potassium hydroxide, sodium carbonate and sodium silicate; organic amines, such as ammonia, ethylamine, propylamine, diethylamine, diethylaminoethanol and triethylamine; quaternary amines, such as tetramethylammonium hydroxide (TMAH); and the like, are used, and a 2.38 mass % TMAH aqueous solution is preferred. A surfactant can also be further added to the developer. The temperature of the developer is preferably 5 to 50° C. (more preferably 25 to 40° C.), and the development time is preferably 10 to 300 seconds (more preferably 30 to 60 seconds). After development, rinsing with water or rinsing treatment can also be performed as necessary.

### [Method for Manufacturing a Processed Substrate]

A processed substrate can be manufactured using the resist pattern manufactured by the method according to the present invention. The method for manufacturing a processed substrate according to the present invention comprises the following processes:
manufacturing a resist pattern by the above-mentioned method; and
(7) processing the underlayer of the resist pattern using the resist pattern as a mask.

The processing in (7) includes not only structural changes but also physical or chemical changes. For example, in the process (7a) to be described below, structurally changing due to etching of the underlayer fall under the processing. For example, in the process (7b) or (7c) to be described below, the physical properties of the target are changed by injecting ions.

A processed substrate can be manufactured by performing dry etching using the resist pattern manufactured by the method according to the present invention as a mask. Therefore, in a preferred embodiment, the method for manufacturing a processed substrate according to the present invention comprises the following processes:
manufacturing a resist pattern by the above-mentioned method; and
(7a) dry-etching the underlayer using the resist pattern as a mask.

Preferably, the underlayer in (7a) is a cured film, an intervening layer, or a substrate (more preferably a substrate). For the intervening layer, there is a case where it is present between a resist pattern and a cured film of the present invention, or a case where it is present between the cured film and a substrate. The latter is more preferable, and examples thereof include a SiON film and a Spin on glass film.

In (7a), it is also a preferred embodiment of the present invention to etch the cured film of the present invention using the resist pattern as a mask to form a cured film pattern, and to etch a substrate using the cured film pattern as a mask. It is also a preferred aspect of the present invention to directly etch the substrate using the resist pattern as a mask. In (7a), it is also preferable as another aspect of the present invention to etch the intervening layer using the resist pattern as a mask to form an intervening layer pattern, and to etch the substrate using the intervening layer pattern as a mask.

The gas in the process (7a) is preferably O₂, CF₄, Ar, CHF₃, Cl₂, BCl₃, or a mixture of any of these (more preferably a mixture of O₂, CF₄ and Ar).

A processed substrate can be manufactured by performing ion etching using the resist pattern manufactured by the method according to the present invention or the underlayer thereof as a mask. Therefore, in another preferred embodiment, the method for manufacturing a processed substrate according to the present invention comprises the following processes:
manufacturing a resist pattern by the above-mentioned method;
(7b) performing ion implantation using the resist pattern as a mask, or (7c) processing the underlayer of the resist pattern using the resist pattern as a mask to form a underlayer pattern, and performing ion implantation using the underlayer pattern as a mask.

In the above (7b) and (7c), the descriptions and preferred examples of the underlayer and the intervening layer are each the same as the above (7a) unless otherwise described. In the above (7b), the target of ion injection is preferably a substrate or an intervening layer (more preferably a substrate). In the above (7c), the underlayer is preferably a cured film or an intervening layer (more preferably a cured film). In the above (7c), the target of ion injection using the underlayer pattern as a mask is preferably a substrate or an intervening layer (more preferably a substrate). Comparing (7b) with (7c), the method including (7c) is more preferable as the method for manufacturing a processed substrate of the present invention.

Ion injection can be performed by a known method using a known ion injection apparatus.

In manufacturing semiconductor devices, liquid crystal display devices, etc., an impurity diffusion layer is formed on the surface of the substrate. The formation of the impurity diffusion layer is usually carried out in two stages, which are introduction and diffusion of impurities. As one of the introduction methods, there is ion implantation (ion injection) in which impurities such as phosphorus and boron are ionized in a vacuum and accelerated by a high electric field to be implanted into the surface of the substrate. The resist pattern or the underlayer pattern is used as a mask when selectively implanting ions of impurities on the surface of the substrate. As the ion acceleration energy at the time of ion injection, an energy load of 10 to 200 keV is applied to the resist pattern, and the mask pattern is sometimes destroyed. Although not to be bound by theory, the cured film of the present invention is preferable for ion injection because it can be made harder and the amount of shrinkage of the film can be reduced even if it is made thicker. Examples of the ion source (impurity element) include ions such as boron, phosphorus, arsenic and argon. Examples of the thin film on the substrate include silicon, silicon dioxide, silicon nitride and aluminum.

### [Method for Manufacturing a Device]

A device can be manufactured by a manufacturing method comprising the above method. The method for manufacturing a device according to the present invention preferably further comprises forming wiring on the processed substrate. Examples of the device include a semiconductor device, a liquid crystal display device, an organic EL display device, a plasma display device, and a solar cell device. Preferably, the device is a semiconductor.

### EXAMPLE

The present invention is described below with reference to various examples. The embodiment of the present invention is not limited to these examples.

In Examples, the mass average molecular weight is measured using GPC.

### <Preparation of a Composition of Example 1>

PGME and PGMEA are used as the organic solvent (B1), and γ-valerolactone is used as the organic solvent (B2). Mixing them with a mass ratio of 67.5:27.5:5 (=PGME:PGMEA: γ-valerolactone) to obtain the solvent (B).
a1 as the hydrocarbon-containing compound (A),
c1 as the component (C) containing a cross-linking group, and
d1 as the acid generator (D) are added to the solvent (B) as solid components so as to make their mass ratio to be 90:9:1.

In Example 1, in order to form a film having a film thickness of 3.0 μm, the solid components are prepared so as to be 29 mass % based on the total mass of the composition. MEGAFACE R-40 (DIC) is added to this as the surfactant (G) so as to be 0.1 mass % based on the total mass of the composition.

This is stirred at room temperature for 30 minutes to obtain a solution. It is visually confirmed that each solid component is completely dissolved. The obtained solution is filtered through a 0.1 μm polyethylene resin filter (Entegris, CWUV031 S2) to obtain a composition of Example 1.

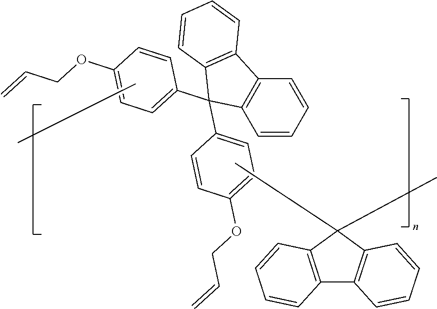

a1: the above polymer, Mw 2,100

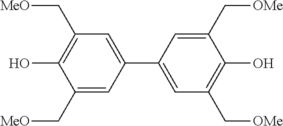 [SMILES: COCc1cc(-c2cc(COC)c(O)c(COC)c2)cc(COC)c1O]

c1: tetramethoxymethyl-bisphenol

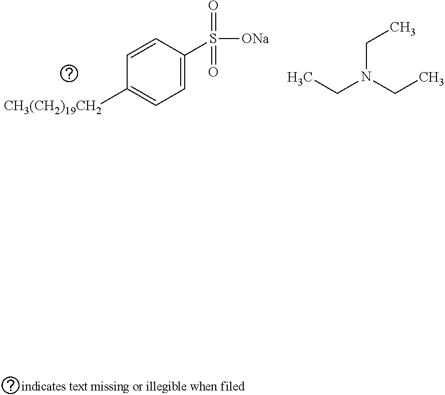

d1: thermal acid generator: dodecylbenzene sulfonic acid and triethylamine salt

### <Preparation of Compositions of Examples 2 to 5, Reference Examples 1 to 5, and Comparative Examples 1 to 5>

The operation is carried out in the same manner as in the preparation of the composition of Example 1 except that the solid component, the type of the solvent, and the addition amount are changed as shown in Table 2. It is visually confirmed that each solid component is completely dissolved, and filtration is performed in the same manner as in the preparation of the composition of Example 1. In accordance with these, compositions of Examples 2 to 5, Reference Examples 1 to 5, and Comparative Examples 1 to 5 are prepared. The composition for forming a film having a film thickness of 3.0 μm is prepared so that the solid component is 29 mass % based on the total mass of the composition. The composition for forming a film having a film thickness of 0.3 μm is prepared so that the solid component is 15 mass % based on the total mass of the composition. MEGAFACE R-40 (DIC) is added as the surfactant (G) so as to be 0.1 mass % based on the total mass regardless of whether the film thickness is 3.0 μm or 0.3 μm.

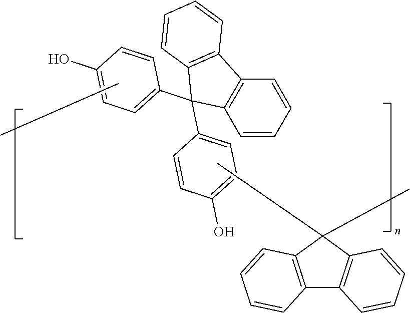

a2: the above polymer, Mw=2,100
a3: novolak resin, which is a random copolymer of m-cresol and p-cresol (mass ratio 6:4), Mw=12,000

TABLE 2

| | Solid component Mass ratio | | | | | (B) Mass ratio | | | | (B2) | Solid |
|---|---|---|---|---|---|---|---|---|---|---|---|
| | (A) | | | (C) | (D) | (B1) | | | | Compound | component |
| | a 1 | a2 | a3 | c1 | d1 | PGMEA | PGME | Anisole | (B2) | name | mass % |
| Example 1 | 90 | — | — | 9 | 1 | 67.5 | 27.5 | — | 5.0 | Y- | 29 |
| | | | | | | | | | | valerolactone | |
| Reference | — | 45 | 45 | 9 | 1 | 100.0 | — | — | — | — | 15 |
| Example 1 | | | | | | | | | | | |
| Comparative | — | 45 | 45 | 9 | 1 | 100.0 | — | — | — | — | 29 |
| Example 1 | | | | | | | | | | | |
| Reference | — | 45 | 45 | 9 | 1 | — | 100.0 | — | — | — | 15 |
| Example 2 | | | | | | | | | | | |
| Comparative | — | 45 | 45 | 9 | 1 | — | 100.0 | — | — | — | 29 |
| Example 2 | | | | | | | | | | | |
| Reference | — | 45 | 45 | 9 | 1 | 70.0 | 30.0 | — | — | — | 15 |
| Example 3 | | | | | | | | | | | |
| Reference | — | 45 | 45 | 9 | 1 | 70.0 | 30.0 | — | — | — | 15 |
| Example 4 | | | | | | | | | | | |
| Comparative | — | 45 | 45 | 9 | 1 | 70.0 | 30.0 | — | — | — | 29 |
| Example 3 | | | | | | | | | | | |
| Comparative | — | 45 | 45 | 9 | 1 | 70.0 | 30.0 | — | — | — | 29 |
| Example 4 | | | | | | | | | | | |
| Comparative | — | 45 | 45 | 9 | 1 | 67.5 | 27.5 | 5.0 | — | — | 29 |
| Example 5 | | | | | | | | | | | |
| Example 2 | — | 45 | 45 | 9 | 1 | 67.5 | 27.5 | — | 5.0 | N-methyl- | 29 |
| | | | | | | | | | | pyrrolidone | |
| Example 3 | — | 45 | 45 | 9 | 1 | 67.5 | 27.5 | — | 5.0 | Y- | 29 |
| | | | | | | | | | | valerolactone | |
| Example 4 | — | 45 | 45 | 9 | 1 | 67.5 | 27.5 | — | 5.0 | dipropylene | 29 |
| | | | | | | | | | | glycol | |
| Example 5 | — | 45 | 45 | 9 | 1 | 67.5 | 27.5 | — | 5.0 | Y- | 29 |
| | | | | | | | | | | butyrolactone | |
| Reference | — | 45 | 45 | 9 | 1 | 67.5 | 27.5 | — | 5.0 | Y- | 15 |
| Example 5 | | | | | | | | | | butyrolactone | |

The physical properties of the solvent used are as shown below.

TABLE 3

| | Boiling point | Dielectric | |
|---|---|---|---|
| | ° C. | constant | δp/(δd + δp + δh) |
| γ-valerolactone | 207.0 | 36.47 | 33.1% |
| N-methyl-pyrrolidone | 202.0 | 32.00 | 32.8% |
| dipropylene glycol | 230.5 | 32.10 | 37.2% |
| γ-butyrolactone | 204.0 | 39.00 | 38.8% |
| anisole | 153.8 | 4.33 | 14.3% |

### <Formation of a Film>

Using a spin coater (Mikasa), each composition is applied on a 4-inch Si bare wafer at 1,500 rpm. As the first heating, heating is performed at 250° C. for 60 seconds using a hot plate in an air atmosphere. The second heating is performed at the temperature shown in Table 4 for 120 seconds using a hot plate in an air atmosphere. As a result, a cured film is obtained from the composition.

### <Measurement of Film Thickness>

A test piece is prepared from the substrate on which a film is formed as described above, an SEM photograph is obtained using JSM-7100F (JEOL), and the film thickness is measured.

### <Measurement of Etching Rate>

Each film on the wafer is subjected to dry etching using the etching system NE-5000N (ULVAC) under the conditions of chamber pressure: 0.17mT, RF power: 200W, gas flow rate: CF₄ (50 sccm), Ar (35 sccm) and 02 (4 sccm), and time: 30 seconds.

The film thickness before etching and the film thickness after etching are measured as described in the above “Measurement of film thickness”, and the difference between the former and the latter is obtained to calculate the etching rate per unit time. The etching rate of the film formed from each composition is calculated with the etching rate of Reference Example 3 being 100%, and is shown in Table 4.

As can be seen when Reference Example 1 and Comparative Example 1, Reference Example 2 and Comparative Example 2, Reference Example 3 and Comparative Example 3, and Reference Example 4 and Comparative Example 4 are compared, the etching resistance is lowered by increasing the film thickness. Reference Examples 1, 2, 3 and 4, in which the film thickness is 0.3 μm, have high etching resistance, but Examples show good etching resistance despite the film thickness of 3.0 μm.

### <Measurement of Film Hardness>

The film hardness of the cured film described above is measured. Using the ENT-2100 indentation tester (Elionix), an indentation load of 10 pN for a film with a thickness of 0.3 μm and 100 pN for a film with a thickness of 3 μm are imposed on each film on the wafer, under the number of measurement of 100 and the step interval of 100 ms. As a result, the indentation hardness (GPa) and the indentation elasticity (GPa) are calculated. The results are shown in Table 4.

The reason for changing the indentation force depending on the film thickness is to match the ratio of the film thickness and the indentation amount of the needle in order to eliminate the factor of the difference in film thickness.

As can be seen when Reference Example 1 and Comparative Example 1, Reference Example 2 and Comparative Example 2, Reference Example 3 and Comparative Example 3, and Reference Example 4 and Comparative Example 4 are compared, the film hardness decreases by increasing the film thickness. As can be seen when Reference Example 3 and Reference Example 4 are compared, raising the heating temperature from 300° C. to 350° C., the film hardness increases at a film thickness of 0.3 μm. On the other hand, as can be seen when Comparative Example 3 and Comparative Example 4 are compared, even if the heating temperature is raised from 300° C. to 350° C., the film hardness does not increase so much at a film thickness of 3.0 μm. Examples show high film hardness even at a film thickness of 3.0 μm. On the other hand, Comparative Example 5, in which anisole having a dielectric constant of 4.33 is used as a solvent, has a low film hardness.

TABLE 4

| | | Heating | | | |
|---|---|---|---|---|---|
| | Film | temper- | | Indentation | Indentation |
| | thick- | ature | Ethching | hardness | elasticity |
| | ness | ° C. | rate | GPa | GPa |
| Example 1 | 3.0 μm | 300 | 96% | 0.62 | 8.69 |
| Reference | 0.3 μm | 300 | 94% | 0.63 | 8.03 |
| Example 1 | | | | | |
| Comparative | 3.0 μm | 300 | 74% | 0.40 | 5.96 |
| Example 1 | | | | | |
| Reference | 0.3 μm | 300 | 94% | 0.64 | 8.00 |
| Example 2 | | | | | |
| Comparative | 3.0 μm | 300 | 74% | 0.44 | 5.97 |
| Example 2 | | | | | |
| Reference | 0.3 μm | 350 | 100% | 0.65 | 8.51 |
| Example 3 | | | | | |
| Reference | 0.3 μm | 300 | 94% | 0.63 | 8.02 |
| Example 4 | | | | | |
| Comparative | 3.0 μm | 350 | 83% | 0.50 | 5.91 |
| Example 3 | | | | | |
| Comparative | 3.0 μm | 300 | 74% | 0.44 | 5.97 |
| Example 4 | | | | | |
| Comparative | 3.0 μm | 300 | 73% | 0.38 | 6.15 |
| Example 5 | | | | | |
| Example 2 | 3.0 μm | 300 | 104% | 0.68 | 8.85 |
| Example 3 | 3.0 μm | 300 | 96% | 0.62 | 8.89 |
| Example 4 | 3.0 μm | 300 | 100% | 0.65 | 8.77 |
| Example 5 | 3.0 μm | 300 | 97% | 0.63 | 8.91 |
| Reference | 0.3 μm | 300 | 107% | 0.70 | 8.90 |
| Example 5 | | | | | |

<Measurement of Amount of Film Shrinkage after Ion Implantation Treatment>

For the cured membrane formed from the compositions shown in Table 5, the amount of membrane shrinkage after ion implantation treatment is measured. Using the device named EXCEED2300H (Nisshin Ion Equipment), the ion implantation treatment is performed at the target depth set to 1 μm under the conditions of a pressurized voltage of 180 kV, an irradiation amount of 10¹⁵ ion/cm², an incident angle of 0°, and an ion type B.

The film thickness before the ion implantation and the film thickness after the ion implantation are measured as described in the above-mentioned “Measurement of film thickness”, and the difference between the former and the latter is obtained, thereby getting the amount of film shrinkage. The results are shown in Table 5.

In Examples, the amount of film shrinkage due to the ion implantation treatment is smaller than that in Comparative Examples.

### <Evaluation of Filling Properties>

The filling properties of the cured film formed from the compositions shown in Table 5 is evaluated. An 8-inch Si processed substrate having a substrate surface, on which a trench pattern having a height of 0.5 μm, a line space ratio of 1:1 and 250 nm is processed, is prepared. Each composition is applied on the processed substrate at 1,500 rpm. As the first heating, heating is performed at 250° C. for 60 seconds using a hot plate in an air atmosphere. The second heating is performed at the temperature shown in Table 5 for 120 seconds using a hot plate in an air atmosphere.

As a result, a cured film is formed from each composition. A test piece is prepared from the substrate on which a film is formed and observed by SEM. The evaluation criteria for filling properties are as follows. The results are shown in Table 5.
A: No voids or bubbles are confirmed, and the trench is filled with a film.
B: Voids and bubbles are confirmed, and the trench is not filled with a film.

TABLE 5

| | | | Amount of film | |
|---|---|---|---|---|
| | Film | Heating | shrinkage after ion | |
| | thick- | temperature | implantation treatment | Filling |
| | ness | ° C. | μm | proprties |
| Comparative | 3.0 μm | 300 | 0.19 | A |
| Example 1 | | | | |
| Comparative | 3.0 μm | 300 | 0.19 | A |
| Example 2 | | | | |
| Comparative | 3.0 μm | 350 | 0.17 | A |
| Example 3 | | | | |
| Comparative | 3.0 μm | 300 | 0.19 | A |
| Example 4 | | | | |
| Comparative | 3.0 μm | 300 | 0.19 | A |
| Example 5 | | | | |
| Example 2 | 3.0 μm | 300 | 0.12 | A |
| Example 3 | 3.0 μm | 300 | 0.14 | A |
| Example 4 | 3.0 μm | 300 | 0.12 | A |
| Example 5 | 3.0 μm | 300 | 0.14 | A |

What is claimed is:

1. A film-forming composition comprising a hydrocarbon-containing compound (A) and a solvent (B):
wherein,
the hydrocarbon-containing compound (A) comprises the unit (A1) represented by the formula (A1): 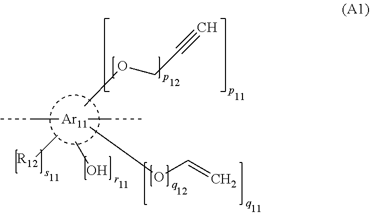
wherein,
Ar₁₁ is a C₆₋₆₀ hydrocarbon group substituted with R₁₁ or unsubstituted,
R₁₁ is C₁₋₂₀ alkyl, amino or C₁₋₂₀ alkylamino,
R₁₂ is I, Br or CN,
p₁₁ is a number of 0 to 5, p₁₂ is a number of 0 to 1, q₁₁ is a number of 0 to 5, q₁₂ is a number of 0 to 1, r₁₁ is a number of 0 to 5, and s₁₁ is a number of 0 to 5, provided that p₁₁, q₁₁ and r₁₁ do not become 0 simultaneously in one unit;
the solvent (B) comprises an organic solvent (B1) and an organic solvent (B2) having a dielectric constant of 20.0 to 90.0; and
the film-forming composition is capable of forming a film having a thickness of 0.5 to 10 μm.

2. The composition according to claim 1, wherein the boiling point of the organic solvent (B2) is 100 to 400° C. at 1 atm; and
δp/(δD+δp+6H) for the organic solvent (B2) is 20 to 50%.

3. The composition according to claim 1, further comprising a component (C) comprising a cross-linking group.

4. The composition according to claim 3, wherein the component (C) comprising a cross-linking group is represented by the formula (Cl): 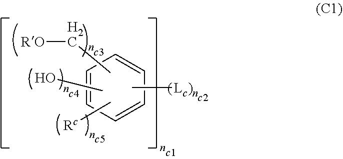
wherein,
n_{c1} is 1, 2, 3 or 4,
n_{c2} is 0 when n_{c1} is 1, and 1 when n_{c1} is 2 or more,
n_{c3} is 0, 1 or 2,
n_{c4} is 1 or 2,
n_{c5} is 0 or 1,
L_{c} is a single bond or a C₁₋₃₀ hydrocarbon group,
R^{c} is each independently C₁₋₆ alkyl or C₆₋₁₀ aryl, and methylene in the alkyl is replaced or not replaced with —O—, and
R′ is hydrogen or methyl.

5. The composition according to claim 1, further comprising an acid generator (D).

6. The composition according to claim 1, having a solid component(s) composition that satisfies the following formula (X):
1.5≤{total number of atoms/(number of C−number of 0)}≤3.5 Formula (X)
wherein,
the number of C is the number of carbon atoms, and
the number of O is the number of oxygen atoms.

7. The composition according to claim 1, further comprising a polymer (E).

8. The composition according to claim 1, which further comprises at least one selected from the group consisting of:
a high carbon material (F);
a surfactant (G); and
an additive (H) selected from the group consisting of an acid, a base, a radical generator, a photopolymerization initiator, and a substrate adhesion enhancer.

9. The composition according to claim 1, wherein the formula (A1) is at least one selected from the group consisting of formulae (A1-1), (A1-2), (A1-3) and (A1-4): 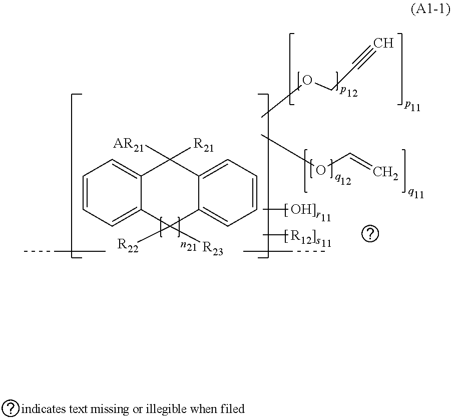
wherein
Ar₂₁ is a C₆₋₅₀ aromatic hydrocarbon group;
R₂₁, R₂₂ and R₂₃ are each independently a C₆₋₅₀ aromatic hydrocarbon group, hydrogen, or a single bond bonded to another structural unit;
n₂₁ is 0 or 1; and
R₁₂, p₁₁, p₁₂, q₁₁, q₁₂, r₁ and s₁₁ have the same meaning as claim 1; 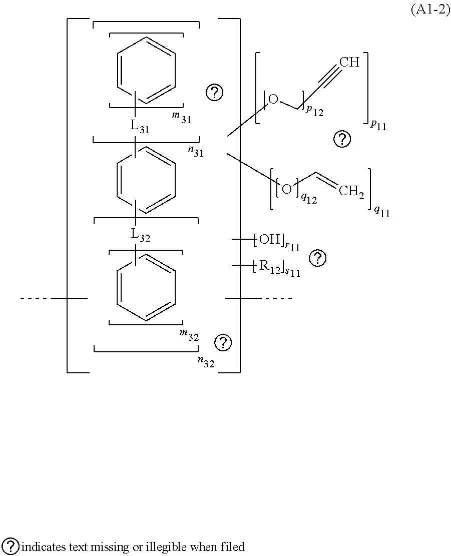
wherein
L₃₁ and L₃₂ are each independently a single bond or phenylene;
n₃₁, n₃₂, m₃₁ and m₃₂ are each independently 0 to 6; and
R₁₂, p₁₁, p₁₂, q₁₁, q₁₂, r₁ and s₁₁ have the same meaning as claim 1; 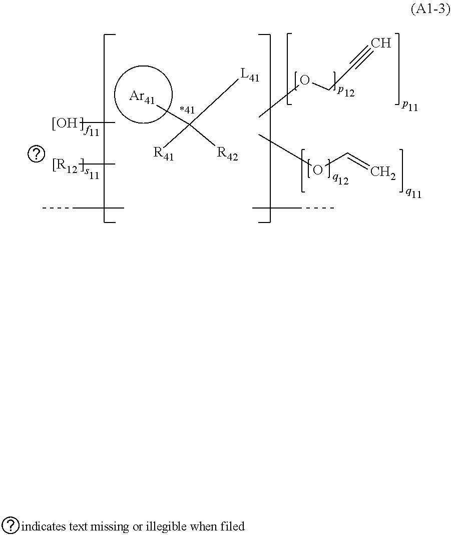
wherein
Ar₄₁ is a C₆₋₅₀ aromatic hydrocarbon group;
R₄₁ and R₄₂ are each independently C₁₋₁₀ alkyl, and R₄₁ and R₄₂ can be bonded to each other to form a ring;
the carbon atom at the position of *41 is a quaternary carbon atom;
L₄₁ is C₆₋₅₀ arylene or a single bond bonded to another structural unit; and
R₁₂, p₁₁, p₁₂, q₁₁, q₁₂, r₁ and s₁₁ have the same meaning as claim 1; and 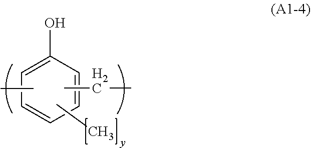
wherein y is 0 to 2.

10. The composition according to claim 1, wherein the hydrocarbon-containing compound (A) is a polymer having a molecular weight of 400 to 100,000.

11. The composition according to claim 8, wherein the high carbon material (F) is included and is represented by the formula (F1): 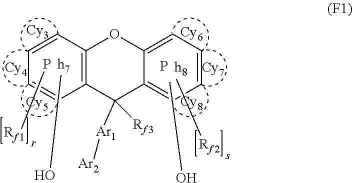
wherein
Ar₁ is a single bond, C₁₋₆ alkyl, C₆₋₁₂ cycloalkyl or C₆₋₁₄ aryl,
Ar₂ is C₁₋₆ alkyl, C₆₋₁₂ cycloalkyl or C₆₋₁₄ aryl,
R_{f1} and R_{f2} are each independently C₁₋₆ alkyl, hydroxy, halogen, or cyano,
R_{f3} is hydrogen, C₁₋₆ alkyl or C₆₋₁₄ aryl,
provided that when Ar₂ is C₁₋₆ alkyl or C₆₋₁₄ aryl and R_{f3} is C₁₋₆ alkyl or C₆₋₁₄ aryl, Ar₂ and R_{f3} can be bonded to each other to form a ring,
r and s are each independently 0, 1, 2, 3, 4 or 5,
at least one of the C_{y3}, C_{y4} and C_{y5} rings surrounded by a broken line is an aromatic hydrocarbon ring fused with the adjacent aromatic hydrocarbon ring Ph₇, and
at least one of the C_{y6}, C_{y7} and C_{y5} rings surrounded by a broken line is an aromatic hydrocarbon ring fused with the adjacent aromatic hydrocarbon ring Ph₈.

12. The composition according to claim 1, wherein the content of the hydrocarbon-containing compound (A) is 3 to 40 mass % based on the composition; and
the content of the solvent (B) is 50 to 97 mass % based on the composition.

13. A method for manufacturing a cured film comprising the following processes:
(1) applying the composition according to claim 1 over a substrate to form a hydrocarbon-containing film; and
(2) heating the hydrocarbon-containing film at a temperature of lower than 340° C.

14. The method according to claim 13, wherein the surface resistivity of the cured film is 10⁹ to 10¹⁶ω□.

15. A method for manufacturing a resist film comprising the following steps:
(1) applying the composition according to claim 1 over a substrate to form a hydrocarbon-containing film;
(2) heating the hydrocarbon-containing film at a temperature of lower than 340° C. to form a cured film;
(3) applying a resist composition above the cured film; and
(4) heating the resist composition to form a resist film.

16. The method according to claim 15, wherein
the heating in (4) is performed at 100 to 250° C. for 30 to 300 seconds in an air atmosphere or a nitrogen gas atmosphere.

17. The method according to claim 14, further comprising:
(5) exposing the resist film to light of a predetermined wavelength; and
(6) developing the resist film to form a resist pattern.

18. The method according to claim 17; further comprising:
(7) processing an underlayer of the resist pattern using the resist pattern as a mask.

19. The method according to claim 17, further comprising:
(7a) dry-etching an underlayer using the resist pattern as a mask:
wherein the underlayer is a cured film, an intervening layer, or a substrate.

20. The method according to claim 17, further comprising an additional step selected from:
(7b) performing ion implantation using the resist pattern as a mask, and
(7c) processing an underlayer of the resist pattern using the resist pattern as a mask to form an underlayer pattern, and performing ion implantation using the underlayer pattern as a mask.
